(19) United States
(12) Patent Application Publication
(10) Pub. No.: US 2026/0324234 A1
(43) Pub. Date: Oct. 15, 2026

(54) DISPLAY BASEPLATE AND DISPLAY DEVICE

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Shunhang Zhang, Beijing (CN); Jiahui Han, Beijing (CN); Tianmin Zhou, Beijing (CN); Pengxia Liang, Beijing (CN); Minghua Xuan, Beijing (CN); Zhenyu Zhang, Beijing (CN); Dongni Liu, Beijing (CN); Zhen Zhang, Beijing (CN); Yunsik Im, Beijing (CN); Peirou Li, Beijing (CN); Lianfu Yu, Beijing (CN)

(73) Assignees: BEIJING BOE TECHNOLOGY DEVELOPMENT CO., LTD., Beijing (CN); BOE TECHNOLOGY GROUP CO., LTD., Beijing (CN)

(21) Appl. No.: 18/880,894

(22) PCT Filed: Dec. 22, 2023
(86) PCT No.: PCT/CN2023/141028

§ 371 Date: Jan. 3, 2025

(51) Int. Cl. H10K 59/131; H10K 59/121

(52) U.S. Cl. CPC H10K 59/1315; H10K 59/1213

(57) ABSTRACT

A display baseplate includes a substrate, and a plurality of first signal lines extending along a first direction and a plurality of second signal lines extending along a second direction that are arranged on a side of the substrate, the plurality of first signal lines and the plurality of second signal lines are arranged in different layers, and orthographic projections of the first signal lines on the substrate intersect with orthographic projections of the second signal line on the substrate to define a plurality of sub-pixels; each sub-pixel includes at least one transistor, the transistor includes an active layer, and the active layer includes a channel part and a first connecting part and a second connecting part that are connected to two sides of the channel part; orthographic projections of the channel part and the first signal lines on the substrate overlap to form a first overlapping area.

### TECHNICAL FIELD

The present disclosure relates to the technical field of displaying, and more particularly to a display baseplate and a display device.

### BACKGROUND

As a typical field of new generation information technology integration and innovation, virtual reality (VR) technology is becoming increasingly mature, and the market development is in a rapid upward trend. In recent years, the global commercialization landing scenarios of VR have become increasingly diverse. In addition to well-known application scenarios such as gaming and entertainment, VR is gradually entering new fields such as healthcare, education, and manufacturing, and the industry penetration rate is also constantly increasing.

### SUMMARY

The present disclosure provides a display baseplate, including a substrate, and a plurality of first signal lines extending along a first direction and a plurality of second signal lines extending along a second direction that are arranged on a side of the substrate, wherein the plurality of first signal lines and the plurality of second signal lines are arranged in different layers, and orthographic projections of the plurality of first signal lines on the substrate intersect with orthographic projections of the plurality of second signal lines on the substrate to define a plurality of sub-pixels; the substrate includes an active area and a non-active area surrounding the active area, the plurality of sub-pixels are located in the active area; each of the plurality of sub-pixels includes at least one transistor, the transistor includes an active layer, and the active layer includes a channel part and a first connecting part and a second connecting part that are connected to two sides of the channel part; orthographic projections of the channel part and the first signal lines on the substrate overlap to form a first overlapping area; and in the first overlapping area, orthographic projections of the channel part and the second signal lines on the substrate overlap, and the first direction and the second direction intersect with each other.

In some embodiments, an end of the first connecting part of the active layer away from the channel part is a first end, an end of the second connecting part of the active layer away from the channel part is a second end; along a direction parallel to the second direction, a spacing between the first end and the second end is greater than an arrangement period of the plurality of sub-pixels along the second direction.

In some embodiments, the first connecting part is connected to the second signal line, orthographic projections of at least part of the first connecting part, and the connected second signal line on the substrate overlap, and an extension direction of the at least part of the first connecting part is parallel to an extension direction of the second signal line.

In some embodiments, along the first direction, a width of the first connecting part is wd1, a width of the second signal line is wd2, 0≤|wd1−wd2|≤1 μm.

In some embodiments, the first connecting part and the second connecting part both extend along the second direction, the channel part extends along a third direction, an included angle of the third direction and the first direction is greater than or equal to 15°, and less than or equal to 60°.

In some embodiments, a transistor of each sub-pixel in an odd number row is a first transistor, a transistor of each sub-pixel in an even number row is a second transistor, an active layer of the first transistor is a first active layer, an active layer of the second transistor is a second active layer, and the first active layer and the second active layer are arranged in the same layer and are separated from each other; and

the first direction is perpendicular to a first plane, and in orthographic projections on the first plane, the second connecting part of the first active layer overlaps with the first connecting part of the second active layer, and the second connecting part of the second active layer overlaps with the first connecting part of the first active layer.

In some embodiments, a pattern obtained by translating the first active layer along the second direction is mirror-symmetric to the second active layer.

In some embodiments, each of the plurality of second signal lines includes a first extension section, a second extension section and a third extension section, the second extension section extends along the second direction and is connected between the first extension section and the third extension section, the first extension section and the third extension section both extend along the first direction and are located on a same side of the second extension section; and

in the first overlapping area, orthographic projections of the channel part of the first active layer and the first extension section on the substrate overlap, and orthographic projections of the channel part of the second active layer and the third extension section on the substrate overlap.

In some embodiments, the display baseplate further includes:
a common signal line, arranged on a side of the first signal lines and the second signal lines away from the substrate, wherein the common signal line includes a first common signal line and a second common signal line intersecting with each other, the first common signal line extends along the first direction, and the second common signal line extends along the second direction; and
an orthographic projection of the first common signal line on the substrate covers an orthographic projection of the first signal line on the substrate at least in the second direction, an orthographic projection of the second common signal line on the substrate covers an orthographic projection of the second signal line on the substrate at least in the first direction.

In some embodiments, each of the plurality of sub-pixels includes a pixel electrode and a common electrode that are arranged in stack, common electrodes of the plurality of sub-pixels are connected to each other, pixel electrodes of different sub-pixels are separated from each other, the pixel electrode is connected to the second connecting part, and the common electrode is connected to the common signal line; and

the pixel electrode is located on a side of the common signal line and the common electrode close to the substrate, and is located on a side of the first signal lines and the second signal lines away from the substrate.

In some embodiments, the common signal line is stacked between the pixel electrode and the common electrode, or the common electrode is stacked between the pixel electrode and the common signal line.

The present disclosure provides a display baseplate, including a substrate, and a plurality of first signal lines extending along a first direction and a plurality of second signal lines extending along a second direction that are arranged on a side of the substrate, wherein the plurality of first signal lines and the plurality of second signal lines are arranged in different layers, and orthographic projections of the plurality of first signal lines on the substrate intersect with orthographic projections of the plurality of second signal lines on the substrate to define a plurality of sub-pixels; the substrate includes an active area and a non-active area surrounding the active area, the plurality of sub-pixels are located in the active area; each of the plurality of sub-pixels includes at least one transistor, the transistor includes an active layer, and the active layer includes a channel part and a first connecting part and a second connecting part that are connected to two sides of the channel part; orthographic projections of the channel part and the first signal lines on the substrate overlap to form a first overlapping area; in the first overlapping area, orthographic projections of the channel part and the second signal lines on the substrate overlap, and the first direction and the second direction intersect with each other; and

transistors connecting two adjacent sub-pixels are located in different planes.

In some embodiments, a transistor of each sub-pixel in an odd number row is a first transistor, a transistor of each sub-pixel in an even number row is a second transistor, the first transistor and the second transistor are located in different planes; and

an active layer of the first transistor is a first active layer, an active layer of the second transistor is a second active layer, and the first active layer and the second active layer are arranged in different layers.

In some embodiments, in orthographic projections on the substrate, a pattern obtained by translating the first active layer along the second direction is mirror-symmetric to the second active layer.

In some embodiments, a ratio of a size of the first active layer along the second direction to an arrangement period of the sub-pixels along the second direction is greater than or equal to 1, and less than or equal to 2; and

a ratio of a size of the second active layer along the second direction to the arrangement period of the sub-pixels along the second direction is greater than or equal to 1, and less than or equal to 2.

In some embodiments, in the first overlapping area, orthographic projections of the channel part of the first active layer and the first connecting part of the second active layer on the substrate overlap, and orthographic projections of the channel part of the second active layer and the first connecting part of the first active layer on the substrate overlap.

In some embodiments, a gate of the first transistor is a first gate, and a gate of the second transistor is a second gate;
each of the plurality of first signal lines includes: a first sub-signal line connected to the first gate, and a second sub-signal line connected to the second gate;
each of the plurality of second signal lines includes:
a third sub-signal line connected to the first connecting part of the first active layer through a first via hole; and
a fourth sub-signal line connected to the first connecting part of the second active layer through a second via hole; and
in orthographic projections on the substrate, the first sub-signal line at least partially covers the second via hole, and the second sub-signal line at least partially covers the first via hole.

In some embodiments, the display baseplate further includes:
a common signal line, arranged on a side of the first signal lines and the second signal lines away from the substrate, wherein the common signal line includes a first common signal line and a second common signal line intersecting with each other, the first common signal line extends along the first direction, and the second common signal line extends along the second direction; and
an orthographic projection of the first common signal line on the substrate covers an orthographic projection of the first signal line on the substrate at least in the second direction, an orthographic projection of the second common signal line on the substrate covers an orthographic projection of the second signal line on the substrate at least in the first direction; and
a width of at least part of the first common signal line in the second direction is greater than a width of the second common signal line in the first direction.

In some embodiments, a gate of the first transistor is a first gate, and a gate of the second transistor is a second gate;
each of the plurality of second signal lines includes: a third sub-signal line connected to the first active layer, and a fourth sub-signal line connected to the second active layer; and
the first gate and the second gate are arranged in different layers, and/or, the third sub-signal line and the fourth sub-signal line are arranged in different layers.

In some embodiments, an orthographic projection of the third sub-signal line on the substrate overlaps with an orthographic projection of the fourth sub-signal line on the substrate.

In some embodiments, each of the plurality of first signal lines includes: a first sub-signal line connected to the first gate, and a second sub-signal line connected to the second gate;

in orthographic projections on the substrate, the first sub-signal line and the second sub-signal line are alternately arranged at equal intervals along the second direction.

In some embodiments, the first gate and the second gate are arranged in different layers, and the third sub-signal line and the fourth sub-signal line are arranged in different layers; and the first gate and the first active layer are located on a side of the third sub-signal line close to the substrate, the second gate and the second active layer are located on a side of the third sub-signal line away from the substrate, and the fourth sub-signal line is located on a side of the second gate and the second active layer away from the substrate.

In some embodiments, the first gate and the second gate are arranged in different layers, and the third sub-signal line and the fourth sub-signal line are arranged in a same layer; and the second gate and the second active layer are located on a side of the first gate and the first active layer away from the substrate, and the third sub-signal line and the fourth sub-signal line are located on a side of the second gate and the second active layer away from the substrate.

In some embodiments, a plurality of first active layers are arranged in an array along the first direction and the second direction, and a plurality of second active layer are arranged in an array along the first direction and the second direction;
in the first direction, an arrangement period of the plurality of first active layers and an arrangement period of the plurality of second active layers are roughly equal to an arrangement period of the plurality of sub-pixels; and
in the second direction, an arrangement period of the plurality of first active layers and an arrangement period of the plurality of second active layers are roughly equal to twice an arrangement period of the plurality of sub-pixels.

In some embodiments, each of the plurality of second signal lines includes: a third sub-signal line connected to the first active layer, and a fourth sub-signal line connected to the second active layer; the third sub-signal line and the fourth sub-signal line are arranged in different layers and connected to different signal input terminals;
a gate of the first transistor is a first gate, and a gate of the second transistor is a second gate, each of the plurality of first signal lines includes: a first sub-signal line connected to the first gate, and a second sub-signal line connected to the second gate;
the non-active area includes: a gate driver circuit including a plurality of shift registers that are cascaded;
wherein the first sub-signal line and the second sub-signal line that are adjacent are connected to a same shift register.

In some embodiments, each of the plurality of second signal lines includes: a third sub-signal line connected to the first active layer, and a fourth sub-signal line connected to the second active layer; wherein the third sub-signal line and the fourth sub-signal line are arranged in different layers and connected to a same signal input terminal, or the third sub-signal line and the fourth sub-signal line are arranged in a same layer;
the non-active area includes: a gate driver circuit including a plurality of shift registers that are cascaded;
wherein different first signal lines are connected to different shift registers, and at least two shift registers connected to different first signal lines are located in the same row.

In some embodiments, each of the plurality of second signal lines includes an extension section extending along the first direction, and in the first overlapping area, orthographic projections of the extension section extending along the first direction and the channel part on the substrate overlap.

In some embodiments, a width of the first signal line in the second direction is less than a width of the channel part in the second direction;
the active area further includes: a plurality of transparent wirings extending along the first direction, the plurality of transparent wirings are connected to the plurality of first signal lines and located between the plurality of first signal lines and the active layer, orthographic projections of the plurality of transparent wirings on the substrate cover orthographic projections of the plurality of first signal lines on the substrate at least in the second direction, the orthographic projections of the plurality of transparent wirings on the substrate cover an orthographic projection of the channel part on the substrate; and
in the second direction, a width of each of the plurality of transparent wirings is greater than a width of each of the plurality of first signal lines, and the width of each of the plurality of transparent wirings is roughly equal to a width of the channel part.

In some embodiments, the display baseplate further includes:
a plurality of light shielding wirings extending along the first direction, and located on a side of the active layer close to the substrate, wherein orthographic projections of the plurality of light shielding wirings on the substrate cover orthographic projections of the plurality of first signal lines on the substrate at least in the second direction;
wherein widths of light shielding wirings at least in two positions are different in the second direction.

In some embodiments, each of the plurality of sub-pixels further includes a pixel electrode, the pixel electrode is connected to the second connecting part through a third via hole, and the plurality of second signal lines are connected to the first connecting part through a fourth via hole;

wherein a distance between the fourth via hole and the channel part is a first distance, a distance between the third via hole and the channel part is a second distance, and the first distance is greater than or equal to the second distance.

The present disclosure provides a display device, including:
the display baseplate according to any one of the above embodiments; and
a source driver circuit connected to the display baseplate, and configured for driving the display baseplate for displaying.

The above description is merely a summary of the technical solutions of the present disclosure. In order to more clearly know the elements of the present disclosure to enable the implementation according to the contents of the description, and in order to make the above and other purposes, features and advantages of the present disclosure more apparent and understandable, the particular embodiments of the present disclosure are provided below.

### BRIEF DESCRIPTION OF THE DRAWINGS

In order to more clearly illustrate the technical solutions of the embodiments of the present disclosure or the related art, the figures that are required to describe the embodiments or the related art will be briefly described below. Apparently, the figures that are described below are embodiments of the present disclosure, and a person skilled in the art can obtain other figures according to these figures without paying creative work. It should be noted that the scale in the attached figures is only for illustration and does not represent the actual scale.

FIG. 1a exemplarily illustrates a schematic diagram of a planar structure of a display baseplate provided by the present disclosure;

FIG. 1b exemplarily illustrates a wiring layout diagram of an active area of a display baseplate;

FIG. 1c exemplarily illustrates a wiring layout diagram of common signal lines in an active area;

FIG. 1d exemplarily illustrates a schematic diagram of cross-sectional structures of a common electrode, a common signal line and a pixel electrode in a sub-pixel;

FIG. 2 exemplarily illustrates a wiring layout diagram of an active area provided by the present disclosure;

FIG. 3 exemplarily illustrates a schematic diagram of a cross-sectional structure of a first type of active area provided by the present disclosure;

FIG. 4 exemplarily illustrates a wiring layout diagram of layers in a first type of active area provided by the present disclosure;

FIG. 5a exemplarily illustrates a schematic diagram of a partial cross-sectional structure of a first type of active area provided by the present disclosure;

FIG. 5b exemplarily illustrates a schematic diagram of another partial cross-sectional structure of a first type of active area provided by the present disclosure;

FIG. 5c exemplarily illustrates a wiring layout diagram of light shielding wirings in an active area;

FIG. 6 exemplarily illustrates a partial wiring layout diagram of a first type of active area provided by the present disclosure;

FIG. 7 exemplarily illustrates a schematic diagram of a cross-sectional structure of a second type of active area provided by the present disclosure;

FIG. 8 exemplarily illustrates a wiring layout diagram of layers in a second type of active area provided by the present disclosure;

FIG. 9 exemplarily illustrates an appearance diagram and a display effect diagram of a second signal line near a fourth via hole;

FIG. 10 exemplarily illustrates a schematic structural diagram and a driving schematic diagram of two types of gate driver circuits provided by the present disclosure;

FIG. 11 exemplarily illustrates a schematic structural diagram and a driving schematic diagram of another two types of gate driver circuits provided by the present disclosure;

FIG. 12 exemplarily illustrates characteristic test results of two groups of thin-film transistor;

FIG. 13 illustrates some characteristic values of a first type of high PPI display baseplate in a first example;

FIG. 14 illustrates some characteristic values of a second type of high PPI display baseplate in a first example;

FIG. 15 illustrates some characteristic values of a third type of high PPI display baseplate in a first example;

FIG. 16 illustrates a value range for some characteristic values of a high PPI display baseplate in a first example;

FIG. 17 illustrates some characteristic values of a display baseplate in a second example;

FIG. 18 illustrates a value range for some characteristic values of a high PPI display baseplate in a second example;

FIG. 19 illustrates a schematic diagram of a planar structure of a display device;

FIG. 20 illustrates a schematic diagram of a virtual display device; and

FIG. 21 illustrates a schematic diagram of a cross-sectional structure of an OLED display panel.

### DETAILED DESCRIPTION

In order to make the purpose, technical solution, and advantages of the embodiment of the present disclosure clearer, the technical solutions according to the embodiments of the present disclosure will be clearly and completely described below with reference to the drawings. Apparently, the described embodiments are merely certain embodiments of the present disclosure, rather than all of the embodiments. All of the other embodiments that a person skilled in the art obtains on the basis of the embodiments of the present disclosure without paying creative work fall within the protection scope of the present disclosure.

In the present disclosure, a transistor refers to an element that includes at least three terminals: a gate electrode, a drain electrode, and a source electrode. A transistor has a channel region between the drain electrode (drain electrode terminal, drain region, or drain) and the source electrode (source electrode terminal, source region, or source), and the current can flow through the drain electrode, the channel region, and the source electrode. In the present disclosure, the channel region refers to the region through which the current mainly flows.

In the present disclosure, the first electrode can be the drain electrode, the second electrode can be the source electrode, or the first electrode can be the source electrode, and the second electrode can be the drain electrode. In the case of using transistors with opposite polarities or when the direction of the current changes during circuit operation, the functions of the “source electrode” and the “drain electrode” are sometimes interchanged. Therefore, in the present disclosure, the “source electrode” and the “drain electrode” can be interchanged.

In the present disclosure, triangles, rectangles, trapezoids, pentagons, hexagons, etc. are not strictly defined and can be approximated as triangles, rectangles, trapezoids, pentagons, hexagons, etc. There may be some small deformations caused by tolerances, such as lead angles, arc edges, and deformations.

For VR display products, due to their small size, their resolution still needs to reach a level of 2K or even 4K or above, which requires compressing the size of the sub-pixels (such as a few micrometers), resulting in a significant decrease in the aperture ratio and transmittance of the sub-pixels, leading to an increase in power consumption and a decrease in display effect.

In related art, the pixel circuit of a liquid crystal display (LCD) panel includes one or two thin-film transistors, which are relatively simple and can achieve ultra-high pixel density (Pixels Per Inch, PPI), that is, the number of pixels per inch. LCD panels have multiple display modes, such as ADS (Advanced Super Dimension Switch) mode, TN (twisted nematic) mode, and VA (Vertical Alignment) mode. In the ADS mode, both the pixel electrode and the common electrode are located on one side of the display baseplate. In the TN mode and the VA mode, the pixel electrode and the common electrode are respectively arranged on opposite sides of the liquid crystal layer, with the pixel electrode located on one side of the display baseplate and the common electrode located on one side of an opposite substrate.

The working principle of the ADS mode is that liquid crystal molecules are in a plane parallel to the substrate, when there is no voltage, the light passes through the lower polarizer and forms a linear polarization parallel to a short axis of the liquid crystal molecules. The polarization direction cannot rotate, so the light is absorbed by the upper polarizer and cannot be emitted. After applying the voltage, a transverse electric field is formed on the left and right sides of the liquid crystal, and the liquid crystal molecules are arranged along the direction of the electric field. After passing through the lower polarizer and the liquid crystal layer, the light becomes elliptically polarized and can be emitted through the upper polarizer.

The working principle of the TN mode is that in a voltage free state, the liquid crystal molecules are twisted and aligned at a 90° angle under the action of the alignment film, and light exits from the upper polarizer after passing through the lower polarizer and the liquid crystal molecules. When the voltage is applied, except for the liquid crystals near the alignment film on the upper and lower sides, most of the liquid crystal molecules are arranged vertically. The light passing through the lower polarizer passes through the liquid crystal layer without deviation. Due to its polarization axis parallel to the upper polarizer, the light is absorbed and cannot be emitted.

The working principle of the VA mode is that the liquid crystal molecules are oriented and arranged perpendicular to the substrate. When there is no voltage, the light passes through the lower polarizer and forms a linear polarization parallel to the short axis of the liquid crystal molecules. The polarization direction cannot rotate, so the light is absorbed by the upper polarizer and cannot be emitted. After applying the voltage, the liquid crystal molecules deflect along the direction of the electric field. After passing through the lower polarizer and the liquid crystal layer, the light becomes elliptically polarized and can be emitted through the upper polarizer.

Taking the ADS mode display baseplate structure as an example to introduce the structure of the display baseplate.

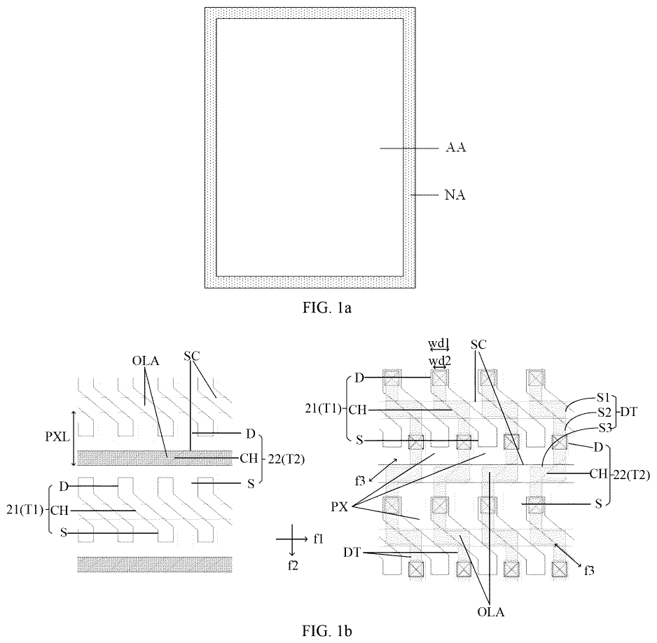

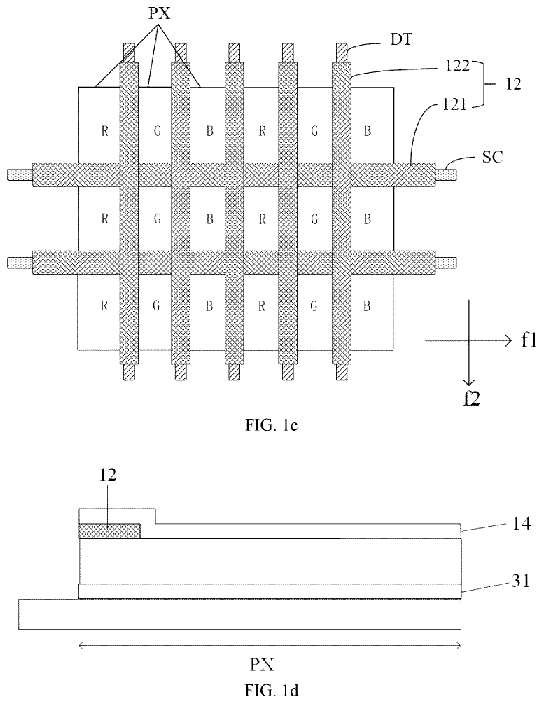

The present disclosure provides a display baseplate, as shown in FIG. 1a and FIG. 1b, the display baseplate includes a substrate 11 (not shown in FIG. 1a and FIG. 1b), and a plurality of first signal lines SC extending along a first direction f1 and a plurality of second signal lines DT extending along a second direction f2 that are arranged on a side of the substrate 11, the plurality of first signal lines SC and the plurality of second signal lines DT are arranged in different layers, and orthographic projections of the plurality of first signal lines SC on the substrate 11 intersect with orthographic projections of the plurality of second signal lines DT on the substrate to define a plurality of sub-pixels PX; the substrate 11 includes an active area AA and a non-active area NA (as shown in FIG. 1a) surrounding the active area AA, the plurality of sub-pixels PX are located in the active area AA; each of the plurality of sub-pixels PX includes at least one transistor, the transistor includes an active layer 21/22, and the active layer 21/22 includes a channel part CH and a first connecting part D and a second connecting part S that are connected to two sides of the channel part CH; a first overlapping area OLA is provided between orthographic projections of the channel part CH and the first signal lines SC on the substrate 11; and in the first overlapping area OLA, orthographic projections of the channel part CH and the second signal lines DT on the substrate 11 overlap, and the first direction f1 and the second direction f2 intersect with each other.

Among them, the first connecting part D is, for example, the first electrode, and the second connecting part S is, for example, the second electrode.

In the present disclosure, the first signal line SC is used as the gate line and the second signal line DT is used as the data line for illustration.

It should be noted that the left diagram in FIG. 1b shows the active layer 21/22 and the first signal lines SC, without the second signal lines DT. The right diagram in FIG. 1b shows the active layer 21/22, the first signal lines SC, and the second signal lines DT.

In some embodiments, as shown in the left diagram in FIG. 1b, an end of the first connecting part D of the active layer 21/22 away from the channel part CH is a first end, an end of the second connecting part S of the active layer 21/22 away from the channel part CH is a second end; along a direction parallel to the second direction f2, a spacing between the first end and the second end is greater than an arrangement period PXL of the plurality of sub-pixels PX along the second direction f2.

As shown in the left diagram in FIG. 1b, a ratio of a size of the active layer 21/22 along the second direction f2 to an arrangement period PXL of the sub-pixels PX along the second direction f2 is greater than or equal to 1, and less than or equal to 2. That is to say, the size of the active layer 21/22 along the second direction f2 is greater than or equal to the arrangement period PXL of the sub-pixels PX along the second direction f2, and less than or equal to twice the arrangement period PXL of the sub-pixels PX along the second direction f2.

By increasing the size of the active layer 21/22 along the second direction f2, the channel lengths of the first transistor T1 and the second transistor T2 can be increased, and the distance between the source and drain via holes and the channel part CH can be increased.

In some embodiments, as shown in the right diagram in FIG. 1b, the first connecting part D is connected to the second signal line DT through the via holes, orthographic projections of at least part of the first connecting part D, and the connected second signal line DT on the substrate 11 overlap, and an extension direction of the at least part of the first connecting part D is parallel to an extension direction of the second signal line DT.

In some embodiments, as shown in the right diagram in FIG. 1b, along the first direction f1, a width of the first connecting part D is wd1, a width of the second signal line DT is wd2, 0≤|wd1−wd2|≤1 μm.

In some embodiments, as shown in the right diagram in FIG. 1b, the first connecting part D and the second connecting part S both extend along the second direction f2, the channel part CH extends along a third direction f3, an included angle of the third direction f3 and the first direction f1 is greater than or equal to 15°, and less than or equal to 60°. For example, the included angle of the third direction f3 and the first direction f1 is 30° or 45°.

In some embodiments, as shown in FIG. 1b, a transistor of each sub-pixel PX in an odd number row is a first transistor T1, a transistor of each sub-pixel PX in an even number row is a second transistor T2, an active layer of the first transistor T1 is a first active layer 21, an active layer of the second transistor T2 is a second active layer 22, and the first active layer 21 and the second active layer 22 are arranged in the same layer and are separated from each other.

As shown in the left diagram in FIG. 1b, the first direction f1 is perpendicular to a first plane (not shown in the figure), and in orthographic projections on the first plane, the second connecting part S of the first active layer 21 overlaps with the first connecting part D of the second active layer 22, and the second connecting part S of the second active layer 22 overlaps with the first connecting part D of the first active layer 21.

For example, in the orthographic projections on the first plane, the second connecting part S of the first active layer 21 of the sub-pixels PX located in a (2n+1)-th row overlaps with the first connecting part D of the second active layer 22 of the sub-pixels PX located in a (2n+2)-th row, and the second connecting part S of the second active layer 22 of the sub-pixels PX located in the (2n+2)-th row overlaps with the first connecting part D of the first active layer 21 of the sub-pixels PX located in a (2n+3)-th row. Among them, n is a positive integer greater than or equal to 0.

In some embodiments, as shown in FIG. 1b, a pattern obtained by translating the first active layer 21 along the second direction f2 is mirror-symmetric to the second active layer 22, and the axis of symmetry extends along the second direction f2.

In some embodiments, as shown in the right diagram in FIG. 1b, each of the plurality of second signal lines DT includes a first extension section S1, a second extension section S2 and a third extension section S3, the second extension section S2 extends along the second direction f2 and is connected between the first extension section S1 and the third extension section S3, the first extension section S1 and the third extension section S3 both extend along the first direction f1 and are located on a same side of the second extension section S2; and in the first overlapping area OLA, orthographic projections of the channel part CH of the first active layer 21 and the first extension section S1 on the substrate 11 overlap, and orthographic projections of the channel part CH of the second active layer 22 and the third extension section S3 on the substrate 11 overlap.

As shown in the right diagram in FIG. 1b, in the first overlapping area OLA, orthographic projections of the channel part CH of the first active layer 21 and a part of the first extension section S1 close to the second extension section S2 on the substrate 11 overlap, and orthographic projections of the channel part CH of the second active layer 22 and a part of the third extension section S3 away from the second extension section S2 on the substrate 11 overlap.

In some embodiments, as shown in FIG. 1c, the display baseplate further includes: a common signal line 12, arranged on a side of the first signal lines SC and the second signal lines DT away from the substrate 11, the common signal line 12 includes a first common signal line 121 and a second common signal line 122 intersecting with each other, the first common signal line 121 extends along the first direction f1, and the second common signal line 122 extends along the second direction f2. An orthographic projection of the first common signal line 121 on the substrate 11 covers an orthographic projection of the first signal line SC on the substrate 11 at least in the second direction f2, an orthographic projection of the second common signal line 122 on the substrate 11 covers an orthographic projection of the second signal line DT on the substrate 11 at least in the first direction f1. As shown in FIG. 1c, the common signal line 12 has a mesh structure.

For example, the common signal line 12 can be made of a metal material with high conductivity.

In some embodiments, as shown in FIG. 1d, each of the plurality of sub-pixels PX includes a pixel electrode 31 and a common electrode 14 that are arranged in stack, common electrodes 14 of the plurality of sub-pixels PX are connected to each other, pixel electrodes 31 of different sub-pixels PX are separated from each other, the pixel electrode 31 is connected to the second connecting part S through a via hole, and the common electrode 14 is connected to the common signal line 12. Among them, the pixel electrode 31 is located on a side of the common signal line 12 and the common electrode 14 close to the substrate 11, and is located on a side of the first signal lines SC and the second signal lines DT away from the substrate 11.

In some embodiments, as shown in FIG. 1d, the common signal line 12 is stacked between the pixel electrode 31 and the common electrode 14 (as shown in FIG. 1d), or the common electrode 14 is stacked between the pixel electrode 31 and the common signal line 12.

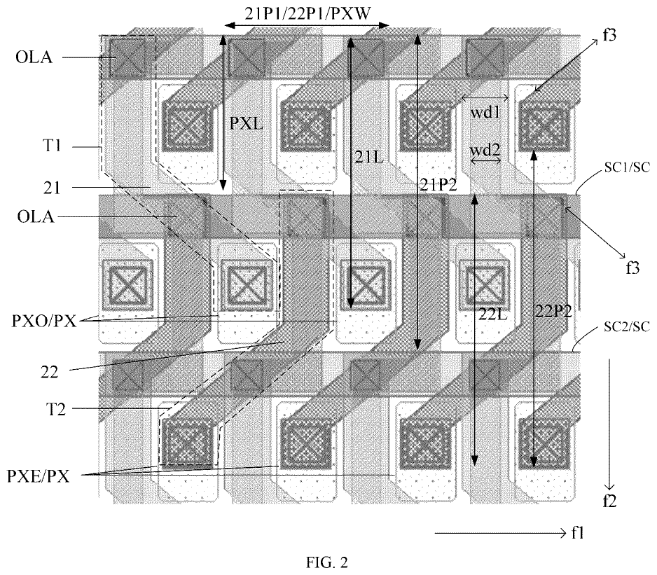

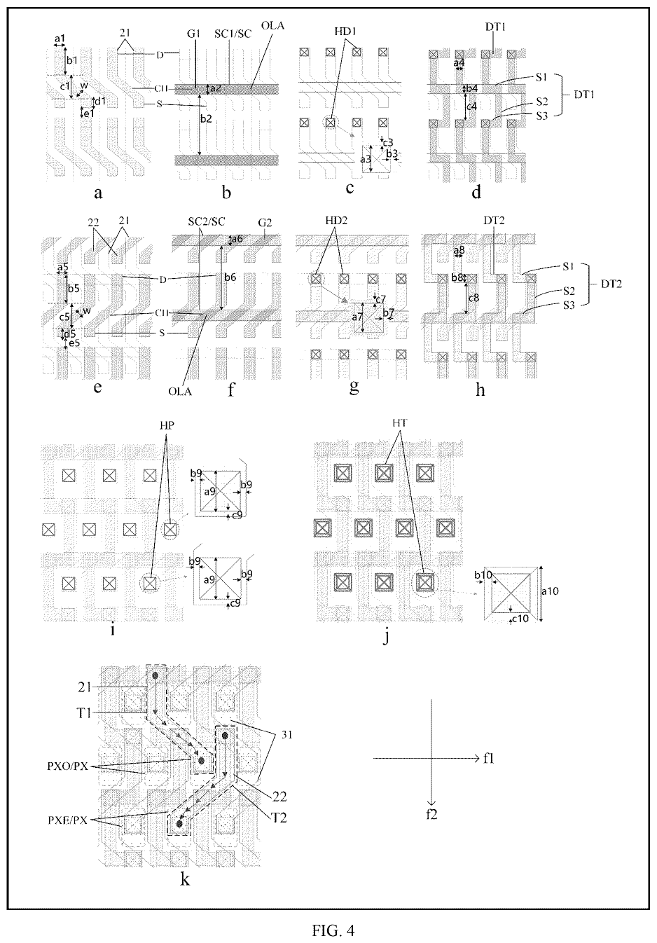

The present disclosure provides a display baseplate, as shown in FIG. 2 and FIG. 4, including a substrate 11, and a plurality of first signal lines SC extending along a first direction f1 and a plurality of second signal lines DT extending along a second direction f2 that are arranged on a side of the substrate 11, the plurality of first signal lines SC and the plurality of second signal lines DT are arranged in different layers, and orthographic projections of the plurality of first signal lines SC on the substrate 11 intersect with orthographic projections of the plurality of second signal lines DT on the substrate 11 to define a plurality of sub-pixels PX; the substrate 11 includes an active area AA and a non-active area NA (as shown in FIG. 1a), surrounding the active area AA, the plurality of sub-pixels PX are located in the active area AA; each of the plurality of sub-pixels PX includes at least one transistor, the transistor includes an active layer 21/22, and the active layer 21/22 includes a channel part CH and a first connecting part D and a second connecting part S that are connected to two sides of the channel part CH; a first overlapping area OLA is provided between orthographic projections of the channel part CH and the first signal lines SC on the substrate 11; in the first overlapping area OLA, orthographic projections of the channel part CH and the second signal lines DT on the substrate 11 overlap, and the first direction f1 and the second direction f2 intersect with each other.

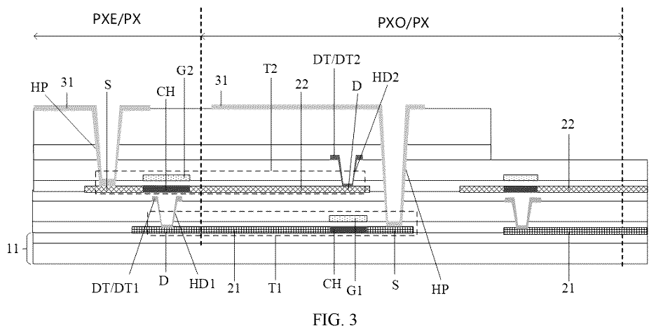

Referring to FIG. 3 and FIG. 7, schematic diagrams of cross-sectional structures of two active areas AA provided by the present disclosure are shown. As shown in FIG. 3 or FIG. 7, the transistors connecting two adjacent sub-pixels PX are located in different planes, that is, the distances between the transistors connecting two adjacent sub-pixels PX and the substrate 11 are not equal.

For example, as shown in FIG. 3 or FIG. 7, the active layers 21/22 of the transistors connecting two adjacent sub-pixels PX are located in different planes, that is, the distances between the active layers 21/22 of the transistors connecting two adjacent sub-pixels PX and the substrate 11 are not equal.

Among them, the first connecting part D is, for example, the first electrode, and the second connecting part S is, for example, the second electrode.

In the present disclosure, the first signal line SC is used as the gate line and the second signal line DT is used as the data line for illustration.

In some embodiments, a transistor of each sub-pixel PX in an odd number row is a first transistor T1, a transistor of each sub-pixel PX in an even number row is a second transistor T2, the first transistor T1 and the second transistor T2 are located in different planes. As shown in FIG. 3 or FIG. 7, an active layer of the first transistor T1 is a first active layer 21, an active layer of the second transistor T2 is a second active layer 22, and the first active layer 21 and the second active layer 22 are arranged in different layers. Among them, a plurality of first active layers 21 are arranged in the same layer, and a plurality of second active layers 22 are arranged in the same layer.

By setting that the active layers 21/22 of transistors in adjacent rows are in different layers, that is, using a double-layer design for the first active layer 21 and the second active layer 22, the design space of the first active layer 21 and the second active layer 22 in the second direction f2 may be increased, and the length of the first active layer 21 and the second active layer 22 in the second direction f2 may be increased, which is beneficial for increasing the channel length of the first transistor T1 and the second transistor T2, and increasing the distance between the source and drain via holes and the channel part CH. In addition, it can also avoid the spacing between the active layers 21/22 arranged on the same layer exceeding the equipment and process limits.

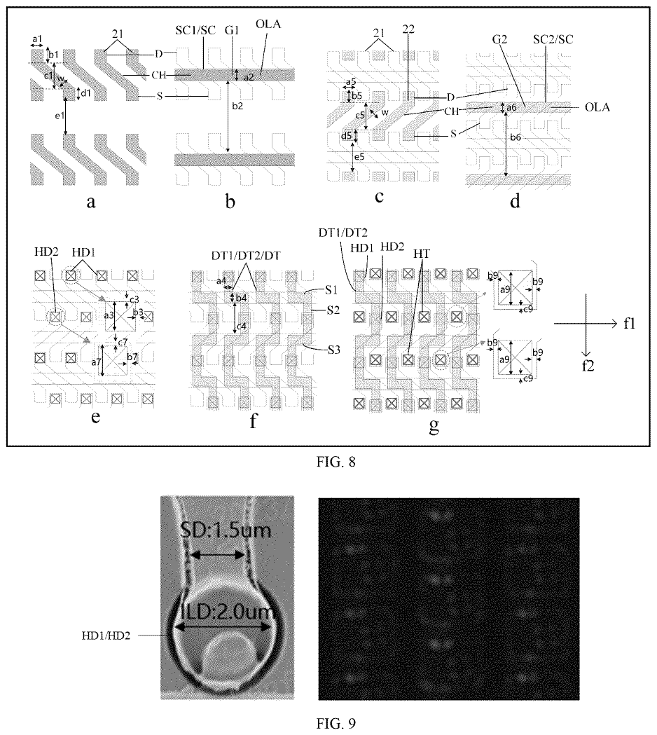

In some embodiments, as shown in diagram e of FIG. 4 or diagram c of FIG. 8, in orthographic projections on the substrate 11, a pattern obtained by translating the first active layer 21 along the second direction f2 is mirror-symmetric to the second active layer 22, and the axis of symmetry extends along the second direction f2.

For example, as shown in diagram e of FIG. 4 or diagram c of FIG. 8, the first active layer 21 and the second active layer 22 have the same size and shape, thereby improving display uniformity.

In some embodiments, as shown in FIG. 2, a ratio of a size 21L of the first active layer 21 along the second direction f2 to the arrangement period PXL of the sub-pixels PX along the second direction f2 is greater than or equal to 1, and less than or equal to 2. That is to say, the size 21L of the first active layer 21 along the second direction f2 is greater than or equal to the arrangement period PXL of the sub-pixels PX along the second direction f2, and less than or equal to twice the arrangement period PXL of the sub-pixels PX along the second direction f2.

In some embodiments, as shown in FIG. 2, a ratio of a size 22L of the second active layer 22 along the second direction f2 to the arrangement period PXL of the sub-pixels PX along the second direction f2 is greater than or equal to 1, and less than or equal to 2. That is to say, the size 22L of the second active layer 22 along the second direction f2 is greater than or equal to the arrangement period PXL of the sub-pixels PX along the second direction f2, and less than or equal to twice the arrangement period PXL of the sub-pixels PX along the second direction f2.

In some embodiments, as shown in FIG. 2, along the first direction f1, a width of the first connecting part D is wd 1, a width of the second signal line DT is wd2, 0≤|wd1−wd2|≤1 μm.

In some embodiments, as shown in FIG. 2, the first connecting part D and the second connecting part S both extend along the second direction f2, the channel part CH extends along a third direction f3, an included angle of the third direction f3 and the first direction f1 is greater than or equal to 15°, and less than or equal to 60°. For example, the included angle of the third direction f3 and the first direction f1 is 30° or 45°.

In some embodiments, as shown in FIG. 2, a plurality of first active layers 21 are arranged in an array along the first direction f1 and the second direction f2, and a plurality of second active layers 22 are arranged in an array along the first direction f1 and the second direction f2.

In some embodiments, as shown in FIG. 2, in the first direction f1, the arrangement period 21P1 of the first active layers 21 is roughly equal to the arrangement period PXW of the sub-pixels PX. In the second direction f2, the arrangement period 21P2 of the first active layers 21 is roughly equal to twice the arrangement period PXL of the sub-pixels PX.

That is to say, the arrangement period 21P1 of the first active layers 21 in the first direction f1 is roughly equal to the arrangement period PXW of the sub-pixels PX in the first direction f1. The arrangement period 21P2 of the first active layers 21 in the second direction f2 is roughly equal to twice the arrangement period PXL of the sub-pixels PX in the second direction f2.

In some embodiments, as shown in FIG. 2, in the first direction f1, the arrangement period 22P1 of the second active layers 22 is roughly equal to the arrangement period PXW of the sub-pixels PX. In the second direction f2, the arrangement period 22P2 of the second active layers 21 is roughly equal to twice the arrangement period PXL of the sub-pixels PX.

That is to say, the arrangement period 22P1 of the second active layers 22 in the first direction f1 is roughly equal to the arrangement period PXW of the sub-pixels PX in the first direction f1. The arrangement period 22P2 of the second active layers 22 in the second direction f2 is roughly equal to twice the arrangement period PXL of the sub-pixels PX in the second direction f2.

In some embodiments, as shown in FIG. 2, the orthographic projection of the first active layer 21 on the substrate 11 overlaps with the orthographic projection of the second active layer 22 on the substrate 11.

In some embodiments, as shown in FIG. 3, in the first overlapping area OLA, orthographic projections of the channel part CH of the first active layer 21 of the sub-pixels PX located in a (2n+1)-th row and the first connecting part D of the second active layer 22 of the sub-pixels PX located in a (2n+2)-th row on the substrate 11 overlap, and orthographic projections of the channel part CH of the second active layer 22 of the sub-pixels PX located in the (2n+2)-th row and the first connecting part D of the first active layer 21 of the sub-pixels PX located in a (2n+3)-th row on the substrate 11 overlap. Among them, n is a positive integer greater than or equal to 0.

That is to say, the first active layer 21 and the second active layer 22 are designed to alternate with each other, which can further increase the channel length and the distance between the source and drain via holes and the channel while saving space.

In some embodiments, as shown in FIG. 3 or FIG. 7, a gate of the first transistor T1 is a first gate G1, and a gate of the second transistor T2 is a second gate G2. Each of the plurality of first signal lines SC includes: a first sub-signal line SC1 connected to the first gate G1, and a second sub-signal line SC2 connected to the second gate G2. Each of the plurality of second signal lines DT includes: a third sub-signal line DT1 connected to the first connecting part D of the first active layer 21 through a first via hole HD1; and a fourth sub-signal line DT2 connected to the first connecting part D of the second active layer 22 through a second via hole HD2. In orthographic projections on the substrate 11, the first sub-signal line SC1 at least partially covers the second via hole HD2, and the second sub-signal line SC2 at least partially covers the first via hole HD1.

For example, in the case where the third sub-signal line DT1 and the fourth sub-signal line DT2 are arranged in different layers, the solution provided by this embodiment can be implemented.

In the embodiment, as shown in FIG. 4, the first via hole HD1 is located at the intersection of the third sub-signal line DT1 and the second sub-signal line SC2, and the second via hole HD2 is located at the intersection of the fourth sub-signal line DT2 and the first sub-signal line SC1.

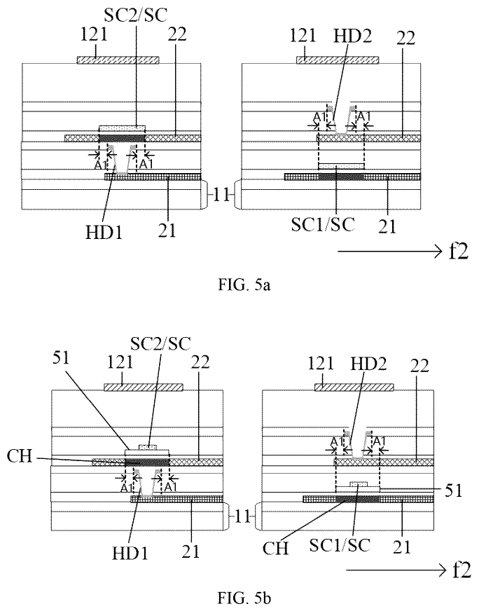

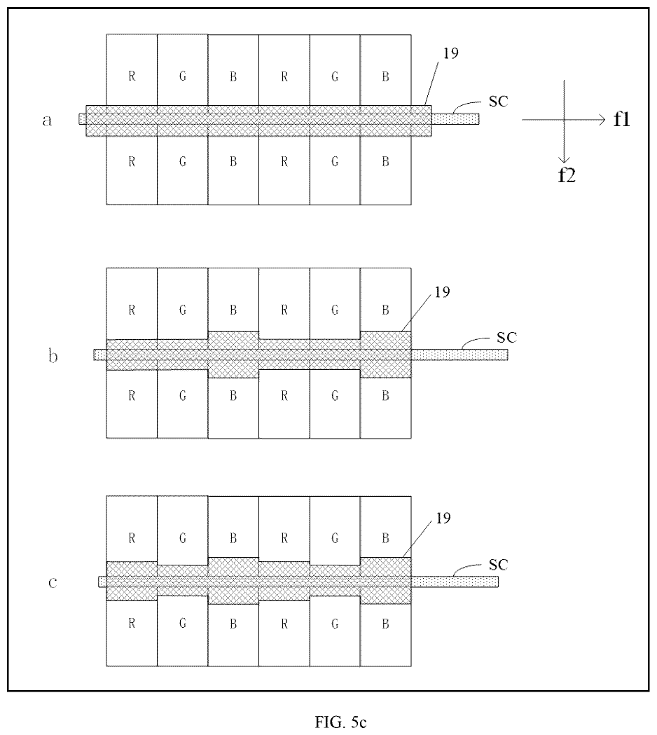

In the embodiment, as shown in FIG. 5a, in the orthographic projections on the substrate 11, the first sub-signal line SC1 completely covers the second via hole HD2, and the second sub-signal line SC2 completely covers the first via hole HD1.

In some embodiments, as shown in FIG. 1c or FIG. 5a, the display baseplate further includes: a common signal line 12, arranged on a side of the first signal lines SC and the second signal lines DT away from the substrate 11, the common signal line 12 includes a first common signal line 121 and a second common signal line 122 intersecting with each other, the first common signal line 121 extends along the first direction f1, and the second common signal line 122 extends along the second direction f2. An orthographic projection of the first common signal line 121 on the substrate 11 covers an orthographic projection of the first signal line SC on the substrate 11 at least in the second direction f2, an orthographic projection of the second common signal line 122 on the substrate 11 covers an orthographic projection of the second signal line DT on the substrate 11 at least in the first direction f1; a width of at least part of the first common signal line 121 in the second direction f2 is greater than a width of the second common signal line 122 in the first direction f1.

Due to the fact that the width of the first common signal line 121 in the second direction f2 is greater than the width of the second common signal line 122 in the first direction f1, the first common signal line 121 can better block the first via hole HD1 and the second via hole HD2, to improve the light leakage at the first via hole HD1 and the second via hole HD2, and not affect the aperture ratio, which is beneficial for reducing power consumption and improving the brightness and contrast of the display baseplate.

For example, as shown in FIG. 5a, in the orthographic projections on the substrate 11, the first sub-signal line SC1 completely covers the second via hole HD2, and the boundary of the first sub-signal line SC1 extends outward by a distance Al relative to the boundary of the second via hole HD2 in the second direction f2. The boundary of the first common signal line 121 further extends outward relative to the boundary of the first sub-signal line SC1 in the second direction f2, and the first common signal line 121 blocks the second via hole HD2.

For example, as shown in FIG. 5a, in the orthographic projections on the substrate 11, the second sub-signal line SC2 completely covers the first via hole HD1, and the boundary of the second sub-signal line SC2 extends outward by the distance Al relative to the boundary of the first via hole HD1 in the second direction f2. The boundary of the first common signal line 121 further extends outward relative to the boundary of the second sub-signal line SC2 in the second direction f2, and the second sub-signal line SC2 and the first common signal line 121 provide dual blocking for the first via hole HD1.

For example, the size of the first sub-signal line SC1 in the second direction f2 is greater than or equal to 1.2 micrometers and less than or equal to 2 micrometers, the size of the second sub-signal line SC2 in the second direction f2 is greater than or equal to 1.2 micrometers and less than or equal to 2 micrometers, and the width of the first common signal line 121 in the second direction f2 is, for example, 2.4 micrometers.

As shown in FIG. 1c, the common signal line 12 has a mesh structure.

For example, the common signal line 12 can be made of a metal material with high conductivity.

In the embodiment, as shown in FIG. 1d, each of the plurality of sub-pixels PX includes a pixel electrode 31 and a common electrode 14 that are arranged in stack, common electrodes 14 of the plurality of sub-pixels PX are connected to each other, pixel electrodes 31 of different sub-pixels PX are separated from each other, the pixel electrode 31 is connected to the second connecting part S through a via hole, and the common electrode 14 is connected to the common signal line 12. Among them, the pixel electrode 31 is located on a side of the common signal line 12 and the common electrode 14 close to the substrate 11, and is located on a side of the first signal lines SC and the second signal lines DT away from the substrate 11.

In some embodiments, as shown in FIG. 1 d, the common signal line 12 is stacked between the pixel electrode 31 and the common electrode 14 (as shown in FIG. 1d), or the common electrode 14 is stacked between the pixel electrode 31 and the common signal line 12.

In some embodiments, as shown in FIG. 3 or FIG. 7, a gate of the first transistor T1 is a first gate G1, and a gate of the second transistor T2 is a second gate G2. Each of the plurality of second signal lines DT includes: a third sub-signal line DT1 connected to the first active layer 21; and a fourth sub-signal line DT2 connected to the second active layer 22. Among them, the first gate G1 and the second gate G2 are arranged in different layers, and/or, the third sub-signal line DT1 and the fourth sub-signal line DT2 are arranged in different layers.

In some embodiments, as shown in FIG. 4, the second signal line DT includes an extension section S1/S3 extending along the first direction f1. In the first overlapping area OLA, orthographic projections of the extension section S1/S3 extending along the first direction f1 and the channel part CH on the substrate 11 overlap.

For example, as shown in FIG. 4, each of the plurality of second signal lines DT includes a first extension section S1, a second extension section S2 and a third extension section S3, the second extension section S2 extends along the second direction f2 and is connected between the first extension section S1 and the third extension section S3, the first extension section S1 and the third extension section S3 both extend along the first direction f1 and are located on a same side of the second extension section S2; and in the first overlapping area OLA, orthographic projections of the channel part CH of the first active layer 21 and the first extension section S1 on the substrate 11 overlap, and orthographic projections of the channel part CH of the second active layer 22 and the third extension section S3 on the substrate 11 overlap.

As shown in FIG. 4, in the first overlapping area OLA, orthographic projections of the channel part CH of the first active layer 21 and a part of the first extension section S1 close to the second extension section S2 on the substrate 11 overlap, and orthographic projections of the channel part CH of the second active layer 22 and a part of the third extension section S3 away from the second extension section S2 on the substrate 11 overlap.

In some embodiments, as shown in FIG. 5b, a width of the first signal line SC in the second direction f2 is less than a width of the channel part CH in the second direction f2; the active area AA further includes: a plurality of transparent wirings 51 extending along the first direction f1, the plurality of transparent wirings 51 are connected to the plurality of first signal lines SC and located between the plurality of first signal lines SC and the active layer 21/22, orthographic projections of the plurality of transparent wirings 51 on the substrate 11 cover orthographic projections of the plurality of first signal lines SC on the substrate 11 at least in the second direction f2, the orthographic projections of the plurality of transparent wirings 51 on the substrate 11 cover an orthographic projection of the channel part CH on the substrate 11; and in the second direction f2, a width of each of the plurality of transparent wirings 51 is greater than a width of each of the plurality of first signal lines SC, and the width of each of the plurality of transparent wirings 51 is roughly equal to a width of the channel part CH.

For example, the material of the transparent wirings 51 is a transparent conductive material, such as metal oxides, for example, ITO, IZO, IGZO, IGO, ZTO, etc. Transparent conductive materials have a higher transmittance of visible light than metal materials.

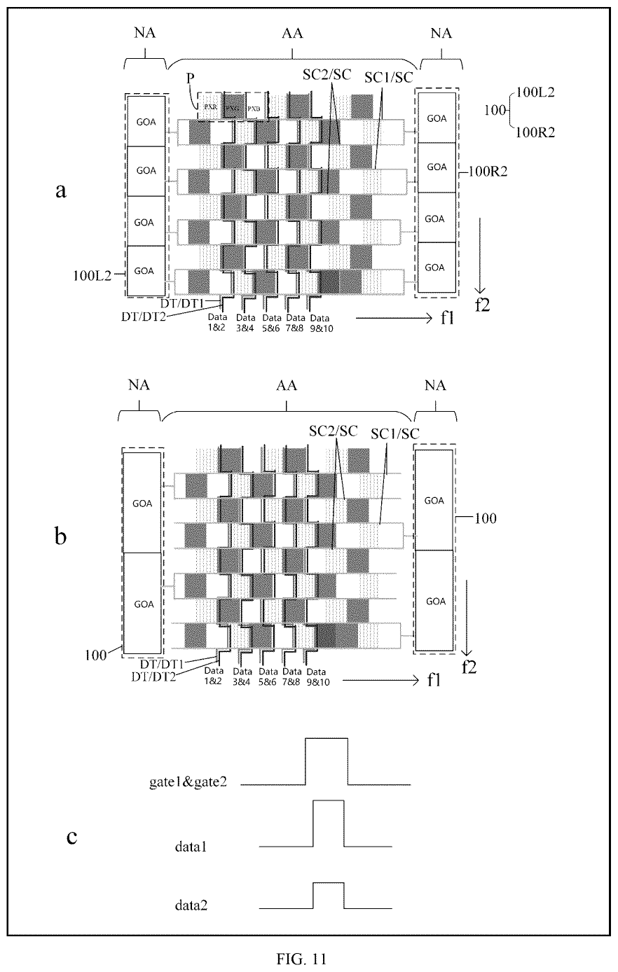

For example, as shown in FIG. 11, the plurality of sub-pixels PX located in a same pixel unit P include a red sub-pixel PXR, a green sub-pixel PXG, and a blue sub-pixel PXB.

In some embodiments, as shown in FIG. 5c, the display baseplate further includes: a plurality of light shielding wirings 19 extending along the first direction f1, and located on a side of the active layer 21/22 close to the substrate 11, orthographic projections of the plurality of light shielding wirings 19 on the substrate 11 cover orthographic projections of the plurality of first signal lines SC on the substrate 11 at least in the second direction f2. Among them, widths of light shielding wirings 19 at least in two positions are different in the second direction f2.

By setting the light shielding wirings 19, the aperture ratio of the sub-pixels PX can be adjusted, and the aperture ratio relationship between the sub-pixels PX of different colors can be adjusted to optimize the display effect.

For example, as shown in diagram b in FIG. 5c, the widths of the light shielding wirings 19 at the corresponding positions of the red sub-pixel PXR and the green sub-pixel PXG in the second direction f2 are the same, which is less than the width of the light shielding wiring 19 at the corresponding position of the blue sub-pixel PXB in the second direction f2.

For example, as shown in diagram c in FIG. 5c, the widths of the light shielding wirings 19 at the corresponding positions of the red sub-pixel PXR, the green sub-pixel PXG, and the blue sub-pixel PXB in the second direction f2 are different from each other. For example, the width of the light shielding wiring 19 at the corresponding position of the blue sub-pixel PXB in the second direction f2 is greater than the width of the light shielding wiring 19 at the corresponding position of the red sub-pixel PXR in the second direction f2, and the width of the light shielding wiring 19 at the corresponding position of the red sub-pixel PXR in the second direction f2 is greater than the width of the light shielding wiring 19 at the corresponding position of the green sub-pixel PXG in the second direction f2.

For example, as shown in diagram a in FIG. 5c, the widths of the light shielding wirings 19 at different positions in the second direction f2 may also be the same, which will not be limited here.

In the case where high photostability and high mobility materials (such as one or more materials in rare earth doped oxides (Ln-OS)) are used in the active layer 21/22, the light shielding wirings 19 can be removed, thereby further improving the pixel aperture ratio.

In specific implementation, there can be multiple stacking arrangements for the first gate G1, the second gate G2, the first active layer 21, the second active layer 22, the third sub-signal line DT1, and the fourth sub-signal line DT2, as illustrated below.

In a first example, as shown in FIG. 3, the first gate G1 and the second gate G2 are arranged in different layers, and the third sub-signal line DT1 and the fourth sub-signal line DT2 are arranged in different layers.

As shown in FIG. 3, the first gate G1 and the first active layer 21 are located on a side of the third sub-signal line DT1 close to the substrate 11, the second gate G2 and the second active layer 22 are located on a side of the third sub-signal line DT1 away from the substrate 11, and the fourth sub-signal line DT2 is located on a side of the second gate G2 and the second active layer 22 away from the substrate 11.

As shown in FIG. 3, the first active layer 21, the first gate G1, the third sub-signal line DT1, the second active layer 22, the second gate G2, and the fourth sub-signal line DT2 are sequentially stacked, with the first active layer 21 arranged close to the substrate 11. In addition, a plurality of pixel electrodes 31 located in different sub-pixels PX are also provided on s side of the fourth sub-signal line DT2 away from the substrate 11.

As shown in FIG. 3, the third sub-signal line DT1 is connected to the first active layer 21 through the first via hole HD1, and the pixel electrode 31 located in the sub-pixels PXO in the odd number row is connected to the first active layer 21 through the third via hole HP, thus completing the construction and connection of the first transistor T1. The third sub-signal line DT1 transmits the data signal to the first active layer 21 through the first via hole HD1, and then to the pixel electrode 31 through the third via hole HP, thereby realizing the charging of the sub-pixels PXO in the odd number row. Referring to diagram k in FIG. 4, the charging path of the sub-pixels PXO in the odd number row is shown.

As shown in FIG. 3, the fourth sub-signal line DT2 is connected to the second active layer 22 through the second via hole HD2, and the pixel electrode 31 located in the sub-pixels PXE in the even number row is connected to the second active layer 22 through the third via hole HP, thus completing the construction and connection of the second transistor T2. The fourth sub-signal line DT2 transmits the data signal to the second active layer 22 through the second via hole HD2, and then to the pixel electrode 31 through the third via hole HP, thereby realizing the charging of the sub-pixels PXE in the even number row. Referring to diagram k in FIG. 4, the charging path of the sub-pixels PXE in the even number row is shown.

The display baseplate provided in this example can be formed by using ten mask processes, as shown in FIG. 4, in the following order: the first active layer 21 (as shown in diagram a in FIG. 4)→the first gate G1 (as shown in diagram b in FIG. 4)→the first via hole HD1 (as shown in diagram c in FIG. 4)→the third sub-signal line DT1 (as shown in diagram d in FIG. 4)→the second active layer 22 (as shown in diagram e in FIG. 4)→the second gate G2 (as shown in diagram f in FIG. 4)→the second via hole HD2 (as shown in diagram g in FIG. 4)→the fourth sub-signal line DT2 (as shown in diagram h in FIG. 4)→the third via hole HP (as shown in diagram i in FIG. 4)→and the pixel electrode 31 (as shown in diagram k in FIG. 4).

In order to reduce the number of the mask processes, in a second example, as shown in FIG. 7, the first gate G1 and the second gate G2 are arranged in different layers, and the third sub-signal line DT1 and the fourth sub-signal line DT2 are arranged in a same layer.

As shown in FIG. 7, the second gate G2 and the second active layer 22 are located on a side of the first active layer 21 away from the substrate 11, the third sub-signal line DT1 and the fourth sub-signal line DT2 are located on a side of the second gate G2 and the second active layer 22 away from the substrate 11.

As shown in FIG. 7, the first active layer 21, the first gate G1, the second active layer 22, the second signal line DT are sequentially stacked, with the first active layer 21 arranged close to the substrate 11. Among them, the second signal line DT includes the third sub-signal line DT1 and the fourth sub-signal line DT2. In addition, a plurality of pixel electrodes 31 located in different sub-pixels PX are also provided on s side of the second signal line DT away from the substrate 11.

As shown in FIG. 7, the third sub-signal line DT1 is connected to the first active layer 21 through the first via hole HD1, and the pixel electrode 31 located in the sub-pixels PXO in the odd number row is connected to the first active layer 21 through the third via hole HP, thus completing the construction and connection of the first transistor T1, and achieving electrical transmission of the sub-pixels PXO in the odd number row. The fourth sub-signal line DT2 is connected to the second active layer 22 through the second via hole HD2, and the pixel electrode 31 located in the sub-pixels PXE in the even number row is connected to the second active layer 22 through the third via hole HP, thus completing the construction and connection of the second transistor T2, and achieving electrical transmission of the sub-pixels PXE in the even number row.

The display baseplate provided in this example can be formed by using eight mask processes, as shown in FIG. 8, in the following order: the first active layer 21 (as shown in diagram a in FIG. 8)→the first gate G1 (as shown in diagram b in FIG. 8)→the second active layer 22 (as shown in diagram c in FIG. 8)→the second gate G2 (as shown in diagram d in FIG. 8)→the first vis hole HD1 and the second via hole HD2 (as shown in diagram e in FIG. 8)→the third sub-signal line DT1 and the fourth sub-signal line DT2 (as shown in diagram f in FIG. 8)→the third via hole HP (as shown in diagram g in FIG. 8)→and the pixel electrode 31. Compared with the first example, the display baseplate provided in this example can save two mask processes and simplify the process steps.

In the first example, the second transistor T2 is located on a side of the first transistor T1 away from the substrate 11. The second transistor T2 does not share a common film layer with the first transistor T1, which can maximize the design space of the first transistor T1 and the second transistor T2 in the second direction f2, and is conducive to increasing the PPI of the display baseplate. The maximum PPI achievable in the first example is greater than that achievable in the second example.

In some embodiments, as shown in FIG. 4 or FIG. 8, the orthographic projection of the third sub-signal line DT1 on the substrate 11 overlaps or completely overlaps with the orthographic projection of the fourth sub-signal line DT2 on the substrate 11. This is beneficial for increasing the aperture ratio, thereby reducing power consumption, and improving display brightness and contrast.

For example, as shown in FIG. 4 or FIG. 8, the third sub-signal line DT1 and the fourth sub-signal line DT2 are both designed as zigzag lines to meet the Delta arrangement of the sub-pixels PX.

In some embodiments, as shown in FIG. 4 or FIG. 8, each first signal line SC includes: a first sub-signal line SC1 connected to the first gate G1, and a second sub-signal line SC2 connected to the second gate G2. In the orthographic projection on the substrate 11, the first sub-signal line SC1 and the second sub-signal line SC2 are alternately arranged at equal intervals along the second direction f2.

As shown in FIG. 4 or FIG. 8, the first gate G1 is the part where the first sub-signal line SC1 overlaps with the first active layer 21, and the second gate G2 is the part where the second sub-signal line SC2 overlaps with the second active layer 22.

For example, the arrangement period of the first sub-signal lines SC1 along the second direction f2 is roughly equal to twice the arrangement period of the sub-pixels PX along the second direction f2, the arrangement period of the second sub-signal lines SC2 along the second direction f2 is roughly twice the arrangement period of the sub-pixels PX along the second direction f2, and the distance between the first sub-signal line SC1 and the second sub-signal line SC2 is roughly equal to the arrangement period PXL of the sub-pixels PX along the second direction f2.

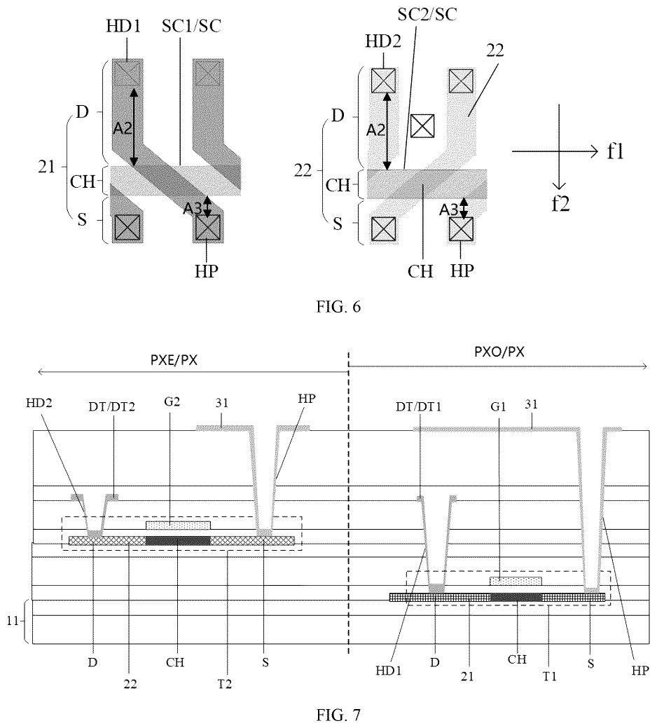

In some embodiments, as shown in FIG. 6, the sub-pixel PX also includes the pixel electrode 31, the pixel electrode 31 is connected to the second connecting part S through the third via hole HP, and the second signal line DT is connected to the first connecting part D through a fourth via hole. The fourth via hole includes the first via hole HD1 and the second via hole HD2. The distances from the first via hole HD1 and the second via hole HD2 to the channel part CH are both the first distance A2, and the distance between the third via hole HP and the channel part CH is the second distance A3. The first distance A2 is greater than or equal to the second distance A3.

For example, as shown in FIG. 4 or FIG. 8, the third via hole HP is located in the opening area of the sub-pixel PX.

For example, the first distance A2 is greater than or equal to 0.5 micrometer and less than or equal to 6 micrometers. The second distance A3 is greater than or equal to 0.5 micrometer and less than or equal to 2 micrometers.

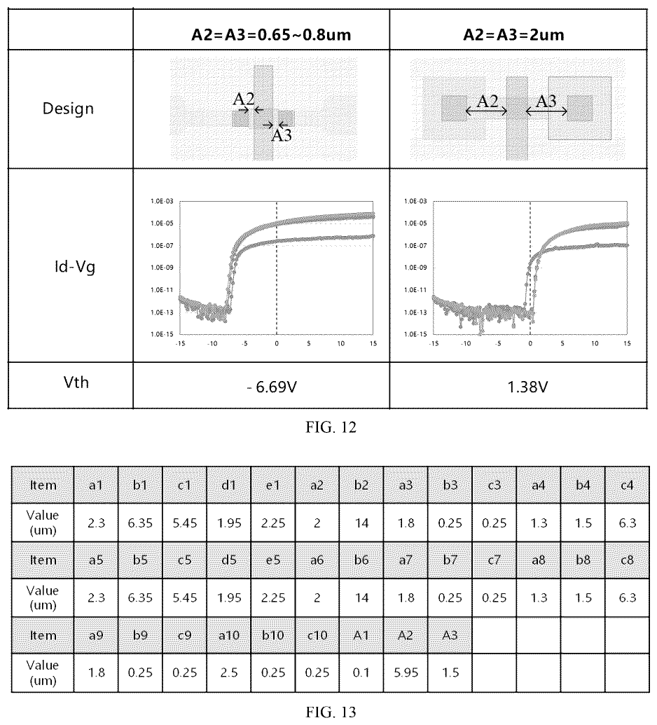

Referring to FIG. 12, the characteristics of two groups of transistors are shown, with one group of transistors having A2-A3=0.65~0.8 μm and the other group of transistors having A2=A3=2 μm. Comparing the test results, it can be found that by setting a larger first distance A2 and second distance A3, the threshold voltage Vth of the transistor can be prevented from experiencing negative bias, thus avoiding short channel effects.

In some embodiments, the first via hole HD1, the second via hole HD2, and the third via hole HP are all the via hole HD1/HD2/HP. As shown in FIG. 4 or FIG. 8, in the orthographic projection on the substrate 11, the boundary of the active layer 21/22 extends outward by a third distance relative to the boundary of the via hole HD1/HD2/HP in the first direction f1 (as shown in b3/b7/b9 in FIG. 4 or FIG. 8), and the boundary of the active layer 21/22 close to the via hole HD1/HD2/HP extends outward by a fourth distance relative to the boundary of the via hole HD1/HD2/HP in the second direction f2 (as shown in c3/c7/c9 in FIG. 4 or FIG. 8), and the third distance is greater than or equal to the fourth distance.

For example, the third distance is greater than or equal to 0 micrometer and less than or equal to 0.5 micrometer. The fourth distance is greater than or equal to 0 micrometer and less than or equal to 0.5 micrometer. In this way, the active layer 21/22 can cover and wrap the via hole HD1/HD2/HP in all directions, maximizing the contact area and avoiding half-hole overlap, thereby reducing the contact resistance of the via hole HD1/HD2/HP and improving display uniformity and yield.

For example, the fourth distance is greater than or equal to −0.25 micrometer and less than or equal to 0.5 micrometer. Among them, the fourth distance is-x micrometers, which means that the boundary of the active layer 21/22 close to the via hole HD1/HD2/HP is indented by x micrometers relative to the boundary of the via hole HD1/HD2/HP in the second direction f2.

By setting that the boundary of the active layer 21/22 close to the via hole HD1/HD2/HP is indented relative to the boundary of the via hole HD1/HD2/HP in the second direction f2, it is beneficial for reducing the arrangement period of the active layers 21/22 in the second direction f2, thereby further improving the PPI of the display baseplate.

In some embodiments, the size of the first via hole HD1 and the second via hole HD2 is greater than or equal to 1.2 micrometers and less than or equal to 2 micrometers, and the size of the third via hole HP is greater than or equal to 1.2 micrometers and less than or equal to 2 micrometers.

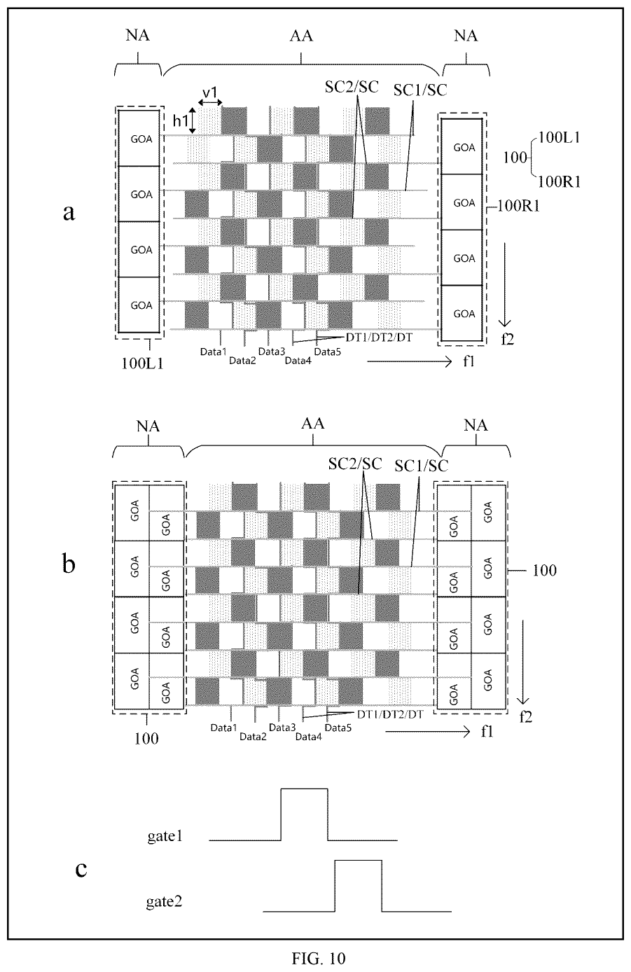

In some embodiments, as shown in diagram a and diagram b in FIG. 10 and FIG. 11, the second signal line DT includes: the third sub-signal line DT1 connected to the first active layer 21, and the fourth sub-signal line DT2 connected to the second active layer 22. The third sub-signal line DT1 and the fourth sub-signal line DT2 are arranged in different layers and connected to different signal input terminals. The gate of the first transistor T1 is the first gate G1, and the gate of the second transistor T2 is the second gate G2. The first signal line SC includes: the first sub-signal line SC1 connected to the first gate G1 and the second sub-signal line SC2 connected to the second gate G2.

As shown in diagram a and diagram b in FIG. 10, the non-active area NA includes: a gate driver circuit 100 including a plurality of shift registers GOA that are cascaded. Among them, different first signal lines SC are connected to different shift registers GOA in a same gate driver circuit 100.

In order to increase the design space of each shift register GOA in the second direction f2, for example, as shown in diagram a in FIG. 10, the gate driver circuit 100 is divided into a first sub-circuit 100L1 and a second sub-circuit 100R1. The first sub-circuit 100L1 and the second sub-circuit 100R1 are located on opposite sides (the left side and the right side as shown in diagram a in FIG. 10) of the active area AA. Among them, the shift register GOA connected to the first signal line SC in the odd number row is located in the first sub-circuit 100L1, and the shift register GOA connected to the first signal line SC in the even number row is located in the second sub-circuit 100R1. In this way, the occupied space of each shift register GOA in the second direction f2 is the arrangement period of two sub-pixels PX in the second direction f2. In this example, the first signal line SC is driven unilaterally, that is, each first signal line SC is connected to a shift register GOA located on one side of the first signal line.

In order to increase the design space of each shift register GOA in the second direction f2, for example, as shown in diagram b in FIG. 10, the first signal line SC is driven bilaterally, that is, each first signal line SC is connected to two shift registers GOA located on both sides of the first signal line. Moreover, at least two shift registers GOA (as shown in diagram b in FIG. 10) connected to different first signal lines SC are located in the same row. By setting at least two columns of shift registers GOA in parallel, the occupied space of each shift register GOA in the second direction f2 is the arrangement period of at least two sub-pixels PX in the second direction f2. However, parallel placement of multiple columns of shift registers GOA will increase the size of the non-active area NA in the first direction f1, that is, the frame width.

In the embodiments shown in diagram a and diagram b in FIG. 10, for example, the third sub-signal line DT1 and the fourth sub-signal line DT2 are arranged in the same layer, or the third sub-signal line DT1 and the fourth sub-signal line DT2 are arranged in different layers and connected to the same signal input terminal. This can reduce the number of source driver chips. Among them, the source driver chip is used to provide data signals to the third sub-signal line DT1 and the fourth sub-signal line DT2.

In order to connect the third sub-signal line DT1 and the fourth sub-signal line DT2 arranged in different layers to the same signal input terminal, for example, the third sub-signal line DT1 and the fourth sub-signal line DT2 can be connected through a via hole in the non-active area NA.

For example, as shown in diagram c in FIG. 10, scanning signals with different timings can be provided to different first signal lines SC, such as a scanning signal gatel and a scanning signal gate2.

In some embodiments, as shown in diagram a and diagram b in FIG. 11, the non-active area NA includes a gate driver circuit 100, which includes a plurality of shift registers GOA that are cascaded. Among them, two adjacent first signal lines SC are connected to the same shift register GOA, that is, adjacent first sub-signal line SC1 and the second sub-signal line SC2 are connected to the same shift register GOA.

In this embodiment, the third sub-signal line DT1 and the fourth sub-signal line DT2 are arranged in different layers and connected to different signal input terminals. For example, the third sub-signal line DT1 can be used to charge the sub-pixels PXO in the odd number row, and the fourth sub-signal line DT2 can be used to charge the sub-pixels PXE in the even number row. By connecting two adjacent first signal lines SC to the same shift register GOA, the scanning signals on the two adjacent first signal lines SC have the same timing, thereby charging the sub-pixels PXO in the odd number row and the sub-pixels PXE in the even number row simultaneously.

As shown in diagram a in FIG. 11, because two adjacent first signal lines SC are connected to the same shift register GOA, the number of the shift registers GOA can be halved, increasing the design space of each shift register GOA in the second direction f2, so that the occupied space of each shift register GOA in the second direction f2 is the arrangement period of two sub-pixels PX in the second direction f2, therefore, there is no need to place a plurality of shift registers GOA in parallel in the first direction f1, which is beneficial for reducing the frame width. For example, the frame width can be compressed from 2 mm to 1.2 mm. In diagram a in FIG. 11, the first signal line SC is driven bilaterally, that is, each first signal line SC is connected to two shift registers GOA located on both sides of the first signal line.

Furthermore, as shown in diagram a in FIG. 11, the gate driver circuit 100 is divided into a third sub-circuit 100L2 and a fourth sub-circuit 100R2, which are located on opposite sides (the left side and the right side as shown in diagram a in FIG. 11) of the active area AA. Among them, the shift register GOA connected to the first signal line SC in the odd number row is located in the third sub-circuit 100L2, and the shift register GOA connected to the first signal line SC in the even number row is located in the fourth sub-circuit 100R2. In this way, the first signal line SC is driven unilaterally, that is, each first signal line SC is connected to one shift register GOA located on one side of the first signal line, the number of the shift registers GOA can be halved again, so that the occupied space of each shift register GOA in the second direction f2 is the arrangement period of four sub-pixels PX in the second direction f2, and there is no need to place the plurality of shift registers GOA in parallel in the first direction f1, which is beneficial for further reducing the frame width.

For example, as shown in diagram c in FIG. 11, the scanning signals (such as gatel and gate2) on the first signal lines SC of adjacent odd number row and even number row have the same timing, so as to charge the sub-pixels PXO in the odd number row and the sub-pixels PXE in the even number row simultaneously.

In some embodiments, as shown in FIG. 11, a plurality of sub-pixels PX are divided into a plurality of pixel units P. The arrangement of the plurality of sub-pixels PX located in the same pixel unit P can be Delta arrangement (as shown in FIG. 1, FIG. 2, FIG. 4, FIG. 8, FIG. 10, and FIG. 11), Real arrangement, Pentile arrangement, etc.

In practical implementation, adopting the Delta arrangement can help further improve the pixel aperture ratio and solve the pixel crosstalk and leakage problems caused by the small arrangement period of the sub-pixels PX in the first direction f1 in the Real arrangement.

For example, shapes of the orthographic projections of the sub-pixels PX on the substrate 11 can include polygons such as rectangles and hexagons, as well as circles, ellipses, sectors, and stars. The shapes of the orthographic projections of the sub-pixels PX on the substrate 11 may be a regular or irregular shape.

For example, the materials of the first active layer 21 and the second active layer 22 may include at least one of: amorphous silicon, low-temperature polycrystalline silicon, or metal oxide semiconductor materials. Among them, the metal oxide semiconductor materials may include one or more of: indium gallium zinc oxide (IGZO), indium gallium tin oxide (IGTO), indium tin zinc oxide (ITZO), indium gallium oxide (IGO), indium gallium zinc tin oxide (IGZTO), indium zinc oxide (IZO), zinc tin oxide (ZTO), indium-free metal oxide (In-free OS), and rare earth doped oxide (Ln-OS). The material of the active layer 21/22 can be amorphous, partially crystalline, single crystal or polycrystalline, or a single-layer or multi-layer structure.

In the case where the materials of the first active layer 21 and the second active layer 22 are low-temperature polycrystalline silicon, in order to reduce leakage current, the pixel circuit of each sub-pixel PX may include two transistors, which may result in a decrease in the aperture ratio.

In the case where the materials of the first active layer 21 and the second active layer 22 are metal oxides such as indium gallium zinc oxide, the pixel circuit of each sub-pixel PX can include a transistor, which is beneficial for improving the aperture ratio.

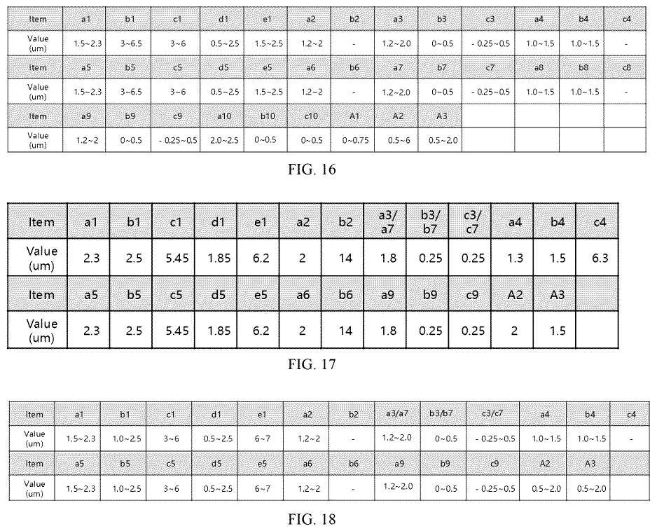

Referring to FIG. 13 to FIG. 15, some characteristic values of the first display baseplate, the second display baseplate, and the third display baseplate in the first example are shown respectively. Referring to FIG. 16, the value range for some characteristic values of the high PPI display baseplate in the first example is shown. Referring to FIG. 17, some characteristic values of a display baseplate in the second example are shown, referring to FIG. 18, the value range for some characteristic values of the high PPI display baseplate in the second example is shown.

In specific implementation, the characteristic values can be adjusted based on the size of sub-pixel PX, PPI, and arrangement of sub-pixels PX. The present disclosure does not limit it.

As shown in FIG. 4 or FIG. 8, a1 represents the width of the first active layer 21, b1 represents the length of the first connecting part D in the first active layer 21, c1 represents the length of the diagonal channel in the first active layer 21, d1 represents the length of the second connecting part S in the first active layer 21, e1 is the spacing between adjacent first active layers 21, a2 represents the width of the first sub-signal line SC1, that is, the channel length L of the first transistor T1, b2 represents the same layer spacing of the first sub-signal line SC1, that is, the spacing between two adjacent first sub-signal lines SC1, a3 represents the size of the first via hole HD1, the first via hole HD1 is located at one end edge of the first connecting part D of the first active layer 21 away from the channel part CH, b3 represents the third distance corresponding to the first via hole HD1, c3 represents the fourth distance corresponding to the first via hole HD1, a4 represents the width of the non-bent position of the third sub-signal line DT1, b4 represents the width of the bending position of the third sub-signal line DT1, and c4 represents the distance between the two bending positions in the third sub-signal line DT1.

As shown in FIG. 4 or FIG. 8, a5 represents the width of the second active layer 22, b5 represents the length of the first connecting part D in the second active layer 22, c5 represents the length of the diagonal channel in the second active layer 22, d5 represents the length of the second connecting part S in the second active layer 22, e5 is the spacing between adjacent second active layers 22, a6 represents the width of the second sub-signal line SC2, that is, the channel length L of the second transistor T2, b6 represents the same layer spacing of the second sub-signal line SC2, that is, the spacing between two adjacent second sub-signal lines SC2, a7 represents the size of the second via hole HD2, the second via hole HD2 is located at one end edge of the first connecting part D of the second active layer 22 away from the channel part CH, b7 represents the third distance corresponding to the second via hole HD2, c7 represents the fourth distance corresponding to the second via hole HD2, a8 represents the width of the non-bent position of the fourth sub-signal line DT2, b8 represents the width of the bending position of the fourth sub-signal line DT2, and c8 represents the distance between the two bending positions in the fourth sub-signal line DT2.

As shown in FIG. 4 or FIG. 8, a9 represents the size of the third via hole HP, the third via hole HP is located at one end edge of the second connecting part S away from the channel part CH, b9 represents the third distance corresponding to the third via hole HP, c9 represents the fourth distance corresponding to the third via hole HP, b10 represents the size of the flat layer sleeve hole HT9 (as shown in diagram j in FIG. 4) located on the periphery of the third via hole HP, b10 represents the distance between the inner wall of the flat layer sleeve hole HT and the third via hole HP in the first direction f1, c10 represents the distance between the inner wall of the flat layer sleeve hole HT and the third via hole HP in the second direction f2.

As shown in FIG. 5a, A1 represents the outward expansion distance of the boundary of the first sub-signal line SC1 relative to the boundary of the second via hole HD2 in the second direction f2, and the outward expansion distance of the boundary of the second sub-signal line SC2 relative to the boundary of the first via hole HD1 in the second direction f2. As shown in FIG. 6, A2 represents the distance from the first via hole HD1 and the second via hole HD2 to the channel part CH, that is, the first distance, and A3 represents the distance between the third via hole HP and the channel part CH, that is, the second distance.

For example, the channel width w of the transistor 1/T2 is greater than or equal to 1.5 micrometers and less than or equal to 2 micrometers, such as 1.8 micrometers.

As shown in FIG. 13 to FIG. 15, the first distance A2 is greater than 4 μm, and the second distance A3 is greater than or equal to 1.2 μm, which can greatly reduce the impact of via etching on the channel part CH.

For example, as shown in FIG. 10, the size v1 of the sub-pixel PX in the first direction f1 is greater than or equal to 5 micrometers and less than or equal to 8 micrometers, such as 6 micrometers. The size h1 of the sub-pixel PX in the second direction f2 is greater than or equal to 6 micrometers and less than or equal to 10 micrometers, such as 8 micrometers, 7 micrometers, and 6 micrometers.

For example, further increase in PPI can be achieved by compressing the size of the sub-pixel PX in the second direction f2. Specifically, the compression of the size of the sub-pixel PX in the second direction f2 can be achieved by compressing one or more characteristic values such as the sizes of the first connecting part D and the second connecting part S in the second direction f2, the interlayer spacing of the active layer 21/22, the fourth distance, the first distance A2, and the second distance A3.

After verification, in the first example, the aperture ratio of the second display baseplate is greater than that of the first display baseplate and the third display baseplate.

For example, as shown in FIG. 13, in the first display baseplate, the third distances b3, b7, and b9 are all equal to 0.25 micrometer, and the fourth distances c3, c7, and c9 are all equal to 0.25 micrometer, that is, the active layer 21/22 wraps around the first via hole HD1, the second via hole HD2, and the third via hole HP in all directions.

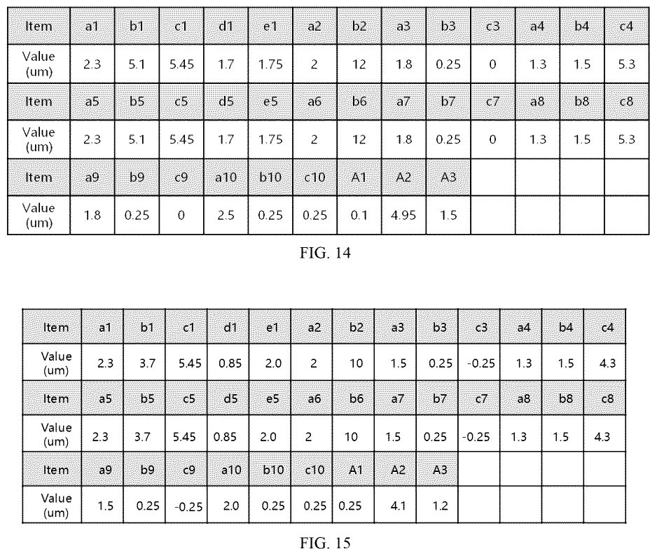

For example, as shown in FIG. 14, in the second display baseplate, the third distances b3, b7, and b9 are all equal to 0.25 micrometer, and the fourth distances c3, c7, and c9 are all equal to 0 micrometer. That is, the active layer 21/22 wraps around the first via hole HD1, the second via hole HD2, and the third via hole HP in the first direction f1. In the second direction f2, the boundaries of the active layer 21/22 close to the first via hole HD1 and the second via hole HD2 are roughly aligned with the boundaries of the first via hole HD1 and the second via hole HD2, and the boundary of the active layer 21/22 close to the third via hole HP are roughly aligned with the boundary of the third via hole HP.

For example, as shown in FIG. 15, in the third display baseplate, the third distances b3, b7, and b9 are all equal to 0.25 micrometer, and the fourth distances c3, c7, and c9 are all equal to −0.25 micrometer. That is, the active layer 21/22 wraps around the first via hole HD1, the second via hole HD2, and the third via hole HP in the first direction f1. In the second direction f2, the boundaries of the active layer 21/22 close to the first via hole HD1 and the second via hole HD2 are indented by 0.25 micrometer relative to the boundaries of the first via hole HD1 and the second via hole HD2. The boundary of the active layer 21/22 close to the third via hole HP are indented by 0.25 micrometers relative to the boundary of the third via hole HP. That is, in the second direction f2, the active layer 21/22 and the first via hole HD1, the second via hole HD2, and the third via hole HP are designed with a semi overlapping structure.

For example, in the first display baseplate, the channel length a2/L of the transistor 1/T2 can also be 3 micrometers. In the second display baseplate, the channel length a2/L can also be 2.5 micrometers, for example. In the third display baseplate, the channel length a2/L is less than or equal to 2 micrometers.

For example, in the first display baseplate, the sizes of the first via hole HD1, the second via hole HD2, and the third via hole HP are, for example, 1.8 micrometers. In the second display baseplate, the sizes of the first via hole HD1, the second via hole HD2, and the third via hole HP are, for example, 1.8 micrometers. In the third display baseplate, the sizes of the first via hole HD1, the second via hole HD2, and the third via hole HP are, for example, less than or equal to 1.5 micrometers.

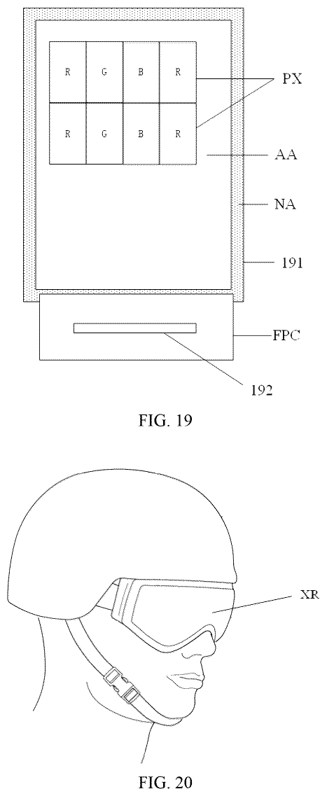

The present disclosure provides a display device, as shown in FIG. 19, including: a display baseplate 191 as provided in any embodiment; and the source driver circuit 192, connected to the display baseplate 191, is used to drive the display baseplate for display.

Persons skilled in the art can understand that the display device provided in the present disclosure has the advantages of the above display baseplate.

For example, as shown in FIG. 19, the source driver circuit is a source driver chip IC, which can be connected to the display baseplate 191 through a flexible circuit board FPC.

The display device provided in the present disclosure can be any product or component with display function, such as high PPI (such as greater than 1500 PPI) display panels, display modules, mobile phones, tablets, televisions, monitors, laptops, digital photo frames, vehicle mounted display devices, smartwatches, fitness wristbands, personal digital assistants, etc. It can also be used in virtual display devices XR such as AR/VR/MR, as shown in FIG. 20.

Among them, the display panel can be a liquid crystal display panel or a self-luminous display panel. The self-luminous display panel has built-in light emitting devices, such as organic light-emitting diodes (OLED), quantum dot light-emitting diodes (QLED), mini light-emitting diodes (Mini LED), or micro light-emitting diodes (Micro LED), etc. In the self-luminous display panel, the display baseplate provided in the present disclosure can serve as the driving backplane for the light emitting devices.

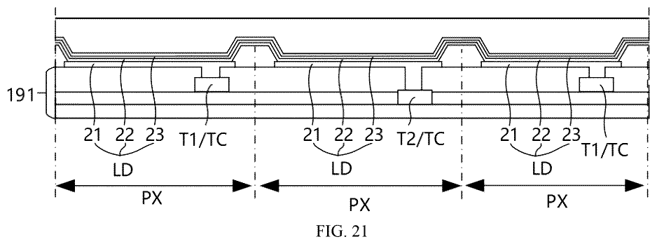

Referring to FIG. 21, a schematic diagram of the cross-sectional structure of an OLED display panel is shown. As shown in FIG. 21, the display baseplate 191 can be the driving backplane of the organic light-emitting diode LD in the OLED display panel. As shown in FIG. 21, the driving transistors TC located in adjacent sub-pixels PX are respectively set as the first transistor T1 and the second transistor T2 in different layers. Among them, the organic light-emitting diode LD includes an anode 21, a luminescent layer 22, and a cathode 23. The anode 21 is located close to the display baseplate 191, and is connected to a driving transistor TC in the display baseplate 191. The driving transistor TC is used to drive the organic light-emitting diode LD to emit light.

In the OLED display panels, the two transistors arranged in different layers can be different types of transistors located within one sub-pixel PX, or the same type of transistor located within two adjacent sub-pixels PX. The driver circuit of each sub-pixel PX can include various types of transistors, such as a driving transistor TC, a reset transistor, a switching transistor, etc.

For example, the two transistors arranged in different layers can be the driving transistor TC and the switching transistor located in one sub-pixel PX. The two transistors arranged in different layers can also be the reset transistor and the switching transistor located in one sub-pixel PX. The two transistors arranged in different layers can also be the reset transistor and the driving transistor TC located in one sub-pixel PX.

For example, two transistors arranged in different layers can be the driving transistors TC located in different sub-pixels PX. The two transistors arranged in different layers can also be the reset transistors located in different sub-pixels PX. The two transistors arranged in different layers can also be the switching transistors located in different sub-pixels PX.

In the present disclosure, the meaning of “plurality of” refers to two or more, and the meaning of “at least one” refers to one or more, unless otherwise specified.

In the present disclosure, the terms “up”, “down”, etc. indicate orientation or positional relationships based on the orientation or positional relationships shown in the accompanying drawings, only for the convenience of describing the present disclosure and simplifying the description, and do not indicate or imply that the device or component referred to must have a specific orientation, be constructed and operated in a specific orientation, and therefore cannot be understood as a limitation of the present disclosure.

In the present disclosure, the terms “including/comprising”, “contain” or any other variation thereof are intended to encompass non-exclusive inclusion, such that a process, method, product, or device including a series of elements includes not only those elements, but also other elements not explicitly listed, or elements inherent to such process, method, product, or device. Without further limitations, the element defined by the statement “including one . . . ” does not exclude the existence of other identical elements in the process, method, product, or device that includes the element in question.

The terms “one embodiment”, “some embodiments”, “exemplary embodiments”, “one or more embodiments”, “examples”, “one example”, “some examples”, etc. referred to in the present disclosure are intended to indicate that specific features, structures, materials, or characteristics related to the embodiment or example are included in at least one embodiment or example of the present disclosure. The schematic representation of the above terms does not necessarily refer to the same embodiment or example. In addition, the specific features, structures, materials, or characteristics described may be included in any appropriate manner in any one or more embodiments or examples.

In the present disclosure, relational terms such as first and second are only used to distinguish one entity or operation from another, and do not necessarily require or imply any such actual relationship or order between these entities or operations.

When describing some embodiments, expressions such as “coupling” and “connection” may be used. For example, in describing some embodiments, the term “connection” may be used to indicate that two or more components have direct physical or electrical contact with each other. For example, in describing some embodiments, the term “coupling” may be used to indicate that two or more components have direct physical or electrical contact. However, the term “coupled” or “communicatively coupled” may also refer to two or more components that do not have direct contact with each other but still cooperate or interact with each other. The embodiments disclosed here are not necessarily limited to the present disclosure.

“At least one of A, B, and C” has the same meaning as “at least one of A, B, or C” and includes the following combinations of A, B, and C: only A, only B, only C, combinations of A and B, combinations of A and C, combinations of B and C, and combinations of A, B, and C.

“A and/or B” includes the following three combinations: only A, only B, and a combination of A and B.

As used in the present disclosure, the term “if” is optionally interpreted as meaning “when” or “at” or “in response to a determination” or “in response to a detection” depending on the context. Similarly, depending on the context, the phrases “if determined . . . ” or “if [stated condition or event] is detected” can be interpreted as referring to “when determined . . . ” or “in response to determining . . . ” or “when [stated condition or event] is detected” or “in response to detecting [stated condition or event]”.

The use of “used for” or “configured as” in the present disclosure implies an open and inclusive language, which does not exclude devices that are applicable or configured to perform additional tasks or steps.

The use of “based on” or “according to” in the present disclosure implies openness and inclusiveness. A process, step, calculation, or other action based on one or more of the conditions or values described, which may be based on other conditions or beyond the values described in practice. The process, steps, calculations, or other actions based on one or more of the stated conditions or values may, in practice, be based on other conditions or beyond the stated values.

As used in the present disclosure, “about”, “roughly”, or “approximately” includes the values stated and the average value within an acceptable deviation range of a specific value, where the acceptable deviation range is determined by persons skilled in the art taking into account the measurement being discussed and the errors associated with the measurement of a specific quantity (i.e., limitations of the measurement system).

As used in the present disclosure, “parallel”, “vertical”, “equal”, and “flush” include the situations described and situations that are similar to the described situations, and the range of such similar situations is within an acceptable deviation range, where the acceptable deviation range is determined by persons skilled in the art taking into account the measurement being discussed and the errors associated with the measurement of a specific quantity (i.e., the limitations of the measurement system). For example, “parallel” includes absolute parallelism and approximate parallelism, where the acceptable deviation range for approximate parallelism can be within 5 degrees of deviation. “Vertical” includes absolute vertical and approximate vertical, where the acceptable deviation range for approximate vertical can also be within 5 °, for example. “Equal” includes absolute equality and approximate equality, where the acceptable deviation range for approximate equality can be, for example, equal. The difference between the two is less than or equal to 5% of either one. “Flush” includes absolute leveling and approximate leveling, where the acceptable deviation range for approximate leveling can be, for example, that the distance between two levels of leveling is less than or equal to 5% of either dimension.

It should be understood that when a layer or component is referred to as being on another layer or substrate, it may be directly on another layer or substrate, or there may be an intermediate layer between the layer or component and another layer or substrate.

The present disclosure describes exemplary embodiments with reference to cross-sectional and/or plan diagrams as idealized illustrative figures. In the attached figures, the thickness of the layers and regions has been enlarged for clarity. Therefore, it can be assumed that there may be changes in the shape relative to the drawings due to factors such as manufacturing technology and/or tolerances. Therefore, the exemplary embodiments should not be interpreted as limited to the shapes of the areas shown in the present disclosure, but rather include shape deviations caused by, for example, manufacturing. For example, etched areas shown as rectangles typically have curved features. Therefore, the areas shown in the figures are essentially illustrative, and their shapes are not intended to show the actual shape of the area of the device, nor are they intended to limit the scope of the exemplary embodiments.

Finally, it should be noted that the above embodiments are only used to illustrate the disclosed technical solution and not to limit it. Although the present disclosure has been described in detail with reference to the aforementioned embodiments, those skilled in the art should understand that they can still modify the technical solutions described in the aforementioned embodiments, or equivalently replace some of the technical features. And these modifications or substitutions do not depart from the essence and scope of the corresponding technical solutions disclosed in the present disclosure.

1. A display baseplate, comprising a substrate, and a plurality of first signal lines extending along a first direction and a plurality of second signal lines extending along a second direction that are arranged on a side of the substrate, wherein the plurality of first signal lines and the plurality of second signal lines are arranged in different layers, and orthographic projections of the plurality of first signal lines on the substrate intersect with orthographic projections of the plurality of second signal lines on the substrate to define a plurality of sub-pixels;
the substrate comprises an active area and a non-active area surrounding the active area, the plurality of sub-pixels are located in the active area;
each of the plurality of sub-pixels comprises at least one transistor, the transistor comprises an active layer, and the active layer comprises a channel part and a first connecting part and a second connecting part that are connected to two sides of the channel part;
orthographic projections of the channel part and the first signal lines on the substrate overlap to form a first overlapping area; and
in the first overlapping area, orthographic projections of the channel part and the second signal lines on the substrate overlap, and the first direction and the second direction intersect with each other.

2. The display baseplate according to claim 1, wherein an end of the first connecting part of the active layer away from the channel part is a first end, an end of the second connecting part of the active layer away from the channel part is a second end; along a direction parallel to the second direction, a spacing between the first end and the second end is greater than an arrangement period of the plurality of sub-pixels along the second direction.

3. The display baseplate according to claim 2, wherein the first connecting part is connected to the second signal line, orthographic projections of at least part of the first connecting part, and a connected second signal line on the substrate overlap, and an extension direction of the at least part of the first connecting part is parallel to an extension direction of the second signal line.

4. The display baseplate according to claim 3, wherein along the first direction, a width of the first connecting part is wdl, and a width of the second signal line is wd2, 0≤|wd1−wd2|≤1 μm.

5. The display baseplate according to claim 1, wherein the first connecting part and the second connecting part both extend along the second direction, the channel part extends along a third direction, an included angle of the third direction and the first direction is greater than or equal to 15°, and less than or equal to 60°.

6. The display baseplate according to claim 1, wherein a transistor of each sub-pixel in an odd number row is a first transistor, a transistor of each sub-pixel in an even number row is a second transistor, an active layer of the first transistor is a first active layer, an active layer of the second transistor is a second active layer, and the first active layer and the second active layer are arranged in the same layer and are separated from each other; and
the first direction is perpendicular to a first plane, and in orthographic projections on the first plane, the second connecting part of the first active layer overlaps with the first connecting part of the second active layer, and the second connecting part of the second active layer overlaps with the first connecting part of the first active layer.

7. The display baseplate according to claim 6, wherein a pattern obtained by translating the first active layer along the second direction is mirror-symmetric to the second active layer.

8. The display baseplate according to claim 6, wherein each of the plurality of second signal lines comprises a first extension section, a second extension section and a third extension section, the second extension section extends along the second direction and is connected between the first extension section and the third extension section, the first extension section and the third extension section both extend along the first direction and are located on a same side of the second extension section; and
in the first overlapping area, orthographic projections of the channel part of the first active layer and the first extension section on the substrate overlap, and orthographic projections of the channel part of the second active layer and the third extension section on the substrate overlap.

9. The display baseplate according to claim 1, wherein the display baseplate further comprises:
a common signal line, arranged on a side of the first signal lines and the second signal lines away from the substrate, wherein the common signal line comprises a first common signal line and a second common signal line intersecting with each other, the first common signal line extends along the first direction, and the second common signal line extends along the second direction; and
an orthographic projection of the first common signal line on the substrate covers an orthographic projection of the first signal line on the substrate at least in the second direction, an orthographic projection of the second common signal line on the substrate covers an orthographic projection of the second signal line on the substrate at least in the first direction.

10. The display baseplate according to claim 9, wherein each of the plurality of sub-pixels comprises a pixel electrode and a common electrode that are arranged in stack, common electrodes of the plurality of sub-pixels are connected to each other, pixel electrodes of different sub-pixels are separated from each other, the pixel electrode is connected to the second connecting part, and the common electrode is connected to the common signal line;
wherein the pixel electrode is located on a side of the common signal line and the common electrode close to the substrate, and is located on a side of the first signal lines and the second signal lines away from the substrate.

11. The display baseplate according to claim 10, wherein the common signal line is stacked between the pixel electrode and the common electrode, or the common electrode is stacked between the pixel electrode and the common signal line.

12. A display baseplate, comprising a substrate, and a plurality of first signal lines extending along a first direction and a plurality of second signal lines extending along a second direction that are arranged on a side of the substrate, wherein the plurality of first signal lines and the plurality of second signal lines are arranged in different layers, and orthographic projections of the plurality of first signal lines on the substrate intersect with orthographic projections of the plurality of second signal lines on the substrate to define a plurality of sub-pixels;
the substrate comprises an active area and a non-active area surrounding the active area, the plurality of sub-pixels are located in the active area;
each of the plurality of sub-pixels comprises at least one transistor, the transistor comprises an active layer, and the active layer comprises a channel part and a first connecting part and a second connecting part that are connected to two sides of the channel part;
orthographic projections of the channel part and the first signal lines on the substrate overlap to form a first overlapping area;
in the first overlapping area, orthographic projections of the channel part and the second signal lines on the substrate overlap, and the first direction and the second direction intersect with each other;
wherein transistors connecting two adjacent sub-pixels are located in different planes.

13. The display baseplate according to claim 12, wherein a transistor of each sub-pixel in an odd number row is a first transistor, a transistor of each sub-pixel in an even number row is a second transistor, the first transistor and the second transistor are located in different planes; and
an active layer of the first transistor is a first active layer, an active layer of the second transistor is a second active layer, and the first active layer and the second active layer are arranged in different layers.

14. The display baseplate according to claim 13, wherein in orthographic projections on the substrate, a pattern obtained by translating the first active layer along the second direction is mirror-symmetric to the second active layer.

15. The display baseplate according to claim 13, wherein a ratio of a size of the first active layer along the second direction to an arrangement period of the sub-pixels along the second direction is greater than or equal to 1, and less than or equal to 2; and
a ratio of a size of the second active layer along the second direction to the arrangement period of the sub-pixels along the second direction is greater than or equal to 1, and less than or equal to 2.

16. The display baseplate according to claim 13, wherein in the first overlapping area, orthographic projections of the channel part of the first active layer and the first connecting part of the second active layer on the substrate overlap, and orthographic projections of the channel part of the second active layer and the first connecting part of the first active layer on the substrate overlap.

17. The display baseplate according to claim 13, wherein a gate of the first transistor is a first gate, and a gate of the second transistor is a second gate;
each of the plurality of first signal lines comprises: a first sub-signal line connected to the first gate, and a second sub-signal line connected to the second gate;
each of the plurality of second signal lines comprises:
a third sub-signal line connected to the first connecting part of the first active layer through a first via hole; and
a fourth sub-signal line connected to the first connecting part of the second active layer through a second via hole; and
in orthographic projections on the substrate, the first sub-signal line at least partially covers the second via hole, and the second sub-signal line at least partially covers the first via hole.

18. The display baseplate according to claim 17, wherein the display baseplate further comprises:
a common signal line, arranged on a side of the first signal lines and the second signal lines away from the substrate, wherein the common signal line comprises a first common signal line and a second common signal line intersecting with each other, the first common signal line extends along the first direction, and the second common signal line extends along the second direction; and
an orthographic projection of the first common signal line on the substrate covers an orthographic projection of the first signal line on the substrate at least in the second direction, an orthographic projection of the second common signal line on the substrate covers an orthographic projection of the second signal line on the substrate at least in the first direction; and
a width of at least part of the first common signal line in the second direction is greater than a width of the second common signal line in the first direction.

19. The display baseplate according to claim 13, wherein a gate of the first transistor is a first gate, and a gate of the second transistor is a second gate;
each of the plurality of second signal lines comprises: a third sub-signal line connected to the first active layer, and a fourth sub-signal line connected to the second active layer; and
the first gate and the second gate are arranged in different layers, and/or, the third sub-signal line and the fourth sub-signal line are arranged in different layers.

20-30. (canceled)

31. A display device, comprising:
the display baseplate according to claim 1; and
a source driver circuit connected to the display baseplate, and configured for driving the display baseplate for displaying.
